(19) United States
(12) Patent Application Publication
(10) Pub. No.: US 2012/0068202 A1
(43) Pub. Date: Mar. 22, 2012

(54) ACTIVE MATRIX SUBSTRATE, METHOD OF MANUFACTURING THE SAME AND DISPLAY EQUIPMENT USING ACTIVE MATRIX SUBSTRATE MANUFACTURED BY THE SAME METHOD

(75) Inventors: Hiroshi Saito, Tokyo (JP); Yoichi Noda, Nagano (JP); Yoshitaka Yamamoto, Osaka (JP)

(73) Assignees: SEIKO EPSON CORPORATION, Shinjuku-ku, Tokyo (JP); SHARP KABUSHIKI KAISHA, Osaka, Osaka (JP)

(21) Appl. No.: 13/258,764

(22) PCT Filed: Mar. 12, 2010
(86) PCT No.: PCT/JP2010/054724

§ 371 Date: Nov. 28, 2011

(30) Foreign Application Priority Data
Mar. 23, 2009 (JP) 2009-069696

(51) Int. Cl. H01L 33/62

(52) U.S. Cl. 257/88; 438/34; 257/E33.062

(57) ABSTRACT

The present invention provides an active matrix substrate and a method of manufacturing the same by decreasing the number of photolithographic processes to reduce the manufacturing cost. The invention also provides a display device using an active matrix substrate manufactured by said manufacturing method. In a process for preparing pixels on an active substrate, which constitutes a display device, a bank or an etching pattern is formed by performing half-tone exposure on a photo resist film or on a black color photo resist film where an active matrix and a display electrode are prepared by coating, and an insulator film is fabricated, and a transparent conductive film and a color filter are prepared by inkjet method.

### FIELD OF THE INVENTION

The present invention relates to a display device, which comprises an active matrix substrate (active substrate; TFT substrate) where thin film elements such as thin film transistors are formed. In particular, the invention relates to the active matrix substrate and a method of manufacturing the same, and to a display device using the active matrix substrate manufactured by this method.

### BACKGROUND ART

In a flat panel type display device (FPD) of active mode such as a liquid display device or an organic electro-luminescent device, a pixel region is formed by using an active matrix, typically represented by a thin film transistor. Description will be given below on a thin film transistor as an example of the active matrix. As the thin film transistor to form the pixel region, an anti-stagger type structure is adopted in most cases. That is, a gate electrode is prepared on an insulator substrate such as a glass plate, and a semiconductor layer and an insulator layer such as channel region or source/drain region and an insulator layer are laminated.

A pixel circuit of a liquid crystal display device is made up by combining the thin film transistor as described above with a scanning line (gate line) to supply signals to a gate electrode, a data line (also called “signal line”) to supply data signals to a source electrode, and one of display electrodes (e.g. a pixel electrode), being connected with the drain electrode and applying voltage on a liquid crystal layer. The source electrode and the drain electrode are switched over during operation, but these are described here as fixed in position. An insulator substrate where this pixel circuit is arranged in matrix form (hereinafter also referred as “pixel array substrate”, “thin transistor substrate (TFT substrate)”, or “active matrix substrate”), and a light shielding film to shield light to color filter or around color filter (generally called “black matrix”), and a counter substrate if necessary where the other of display electrodes (also called “counter electrode” or “common electrode”) are attached together, and by sealing a liquid crystal between them, a liquid crystal panel is made up. IPS mode or FFS mode is also known, in which the common electrode is disposed on active substrate side. Peripheral members such as driver circuit, backlight, etc. are mounted on the liquid crystal panel, and the liquid crystal display device is composed. When the pixel electrode or a counter electrode is used as one of the display electrodes, the counter electrode or the pixel electrode is referred as the other of display electrodes. In the embodiments to be described later, description will be given by referring one of them as a pixel electrode or a counter electrode, and the other is referred as a counter electrode or a pixel electrode.

A method to reduce the number of photolithographic processes of the active matrix substrate as described above is disclosed in the Patent Document 1. In the Patent Document 1, a gate insulator film, a semiconductor layer where silicon is preferably used, and an ohmic contact layer (n⁺ layer) are sequentially formed on a substrate where a gate line is prepared by chemical vapor deposition (CVD) method. Further, a metal thin film, which is to be a source electrode and a drain electrode, is formed on it by sputtering. Then, a photosensitive resist (photo resist) is coated on it. By a photolithographic process using half-tone exposure method, patterning of the source electrode and the drain electrode, the formation of islands (active layer islands), and removal of etching on channel region of the ohmic contact layer are carried out at the same time.

Also, the Patent Document 2 describes a method to form an active matrix substrate of TN mode, MVA mode and IPS mode by performing half-tone exposure method by two times, i.e. by four photolithographic processes in the method of manufacturing active matrix substrate using the half-tone exposure method.

There are many cases where color filter is disposed on the counter substrate. According to the Patent Document 3, the color filter is disposed—not on the counter electrode, but on the pixel electrode of the active matrix substrate. To form this color filter, resist is placed by patterning all over the surface of the pixel region to prepare banks. In recesses (grooves) formed by these banks, a colored ink is coated to prepare color unit pixels (color cells) of each color. Then, an ink containing a black color material is dropped around the color cells and is coated, and a light shielding layer (black matrix) is prepared.

According to the Patent Document 4, an opening region is provided between the thin film transistors (TFT) of the active matrix substrate. Then, a curing ink is dropped by inkjet method, and the color filter is prepared by curing, and a pixel electrode is formed on it.

The Patent Document 5 discloses a method, according to which a gate insulator film, an island of semiconductor layer, and a channel region are formed on an insulator substrate where the gate line and a storage capacity line are prepared. Then, a groove for forming a data line, a source electrode, and a drain electrode, and a color filter and a pixel electrode is prepared by a bank of polyimide film. Then, an ink is dropped as necessary into grooves of each bank, and it is coated. In particular, in the grooves of the banks to prepare the pixel electrode, an ink for preparing color filter is dropped and coated. Then, an electro-conductive ink, which is to be the pixel electrode, is dropped on its upper surface and is coated. The pixel electrode and a part of the drain electrode are connected together, and a part of the data line and a part of the source electrode are connected, and the active matrix substrate is manufactured.

### PRIOR ART REFERENCES

### [Patent Documents]

| | |
|---|---|
| [Patent Document 1] | JP-A-10-163174 |
| [Patent Document 2] | JP-A-2007-310334 |
| [Patent Document 3] | JP-A-7-134290 |
| [Patent Document 4] | JP-A-9-292633 |
| [Patent Document 5] | JP-A-2003-315829 |

### DISCLOSURE OF THE INVENTION

### Problem to be Solved by the Invention

In the manufacture of the liquid crystal display device as described above, a thin film is formed by vapor deposition method under vacuum condition by CVD or sputtering. For the patterning of the thin film thus formed, processes of coating, mask exposure, developing of photo resist are performed, and unnecessary regions are removed by etching. These photolithographic processes are repeatedly performed. As a result, many processes are required for the manufacture of the active matrix substrate, and this leads to higher manufacturing cost.

In the liquid crystal display device where the color filter is disposed on the counter substrate, by giving consideration on position alignment accuracy between light transmitting region of pixel and color filter on the active matrix substrate, a black matrix is prepared so that each cell of the color filter will be smaller than the light transmitting region of the pixel electrode. As a result, numerical aperture of the pixel is too small, and this results in the increase of power consumption in the manufacture of the liquid crystal display device.

Also, a method for forming the color filter on pixel array of the active matrix substrate is proposed, but photolithographic processes are required to manufacture an exclusive bank for the formation of the color filter, and the number of manufacturing processes is not sufficiently reduced.

It is an object of the present invention to provide an active matrix substrate and a method of manufacturing the same by reducing the number of photolithographic processes and to decrease the manufacturing cost, and also to provide a display device using the active matrix substrate manufactured by this manufacturing method.

### Means for Solving the Problems

The present invention is characterized in that a method for forming a photo resist film by resist coating method, preferably by a slit coating method, is adopted as a process for preparing a thin film matrix such as a thin film transistor on an active substrate of a display device, and that a half-tone exposure method is adopted for patterning of the photosensitive resist film.

### Effects of the Invention

The present invention is characterized in that the half-tone exposure method is applied for the preparation of bank grooves formed by resist, which is a receptor of ink by inkjet method of manufacturing the active matrix substrate and the liquid crystal display device by reducing the number of processes as a whole and for the manufacture of them at lower cost. In the following, the recess (bank groove) surrounded by the bank may be simply referred as “bank”.

To cope with the problem that a light transmitting region of the display device is smaller than the light transmitting region of the pixel electrode because of the alignment accuracy with the counter substrate in the liquid crystal display device, the color filter is prepared on pixel array of the active matrix substrate, and numerical aperture can be improved by using the bank for the preparation of color filter in common with the bank for the preparation of pixel electrode.

Through the preparation of the banks shared in common by using the half-tone exposure method, etching is performed on the gate insulator film to cover the terminal region of the gate line and the terminal region of the data line. Also, by exposing the data line and connection of its terminal region, the number of manufacturing processes can be extensively reduced, and numeral aperture of the display device can also be extremely improved. As a result, power consumption for the manufacture of the liquid crystal display device can be decreased. Further, as described above, by preparing the color filter on pixel array of the active matrix substrate, alignment accuracy with the counter substrate is not required. Thus, a substrate made of a material different from the material of the active matrix substrate can be used as the material of the counter electrode. This makes it possible to adopt an inexpensive glass substrate or a plastic substrate with higher light transmittance, and this contributes to extensive reduction of material costs.

For the liquid crystal display device of FFS mode, the color filter is first prepared on a pixel of active matrix substrate where the common line is formed on the same layer as the gate line and the gate electrode. After forming a transparent pixel electrode on the color filter by allover deposition, the interlayer insulator film is deposited by CVD. Photo resist is coated on it, and the patterning is performed by the half-tone exposure method, and a bank is formed, which is made of a resist material with high light transmitting property for forming comb-like common electrode (common electrode; counter electrode). Then, the interlayer insulator film of the common electrode connection for connecting the common electrode with the common line is removed and the common electrode connecting electrode is exposed. After removing the bank material, which covers bottom surface of the bank groove for forming comb-like electrode by ashing, a comb-like transparent common electrode is formed by inkjet method on comb-like resist pattern. As a result, the number of processes can be extensively reduced, and numeral aperture of the display device can be extremely improved. A substrate made of a material different from the material of the active matrix substrate can be used as the material of the counter substrate. By adopting an inexpensive glass substrate or a plastic substrate with higher light transmittance, it is possible to provide a display device by extensively reducing the material costs.

### BRIEF DESCRIPTION OF THE DRAWINGS

FIG. 1 is a drawing to explain steps of a first photolithographic process and steps of a second photolithographic process according to the Embodiment 1 of the present invention;

FIG. 2A is a plan view to explain a process in the Embodiment 1 of the invention;

FIG. 2B is a cross-sectional view along the line A-A in FIG. 2A;

FIG. 2C is a cross-sectional view to explain the process subsequent to the process shown in FIG. 2B along the line A-A in FIG. 2A;

FIG. 3A is a plan view of an essential portion of an active matrix substrate to explain thin film transistor, data line, source electrode and drain electrode as prepared in the second photolithographic process shown in FIG. 1;

FIG. 3B is a cross-sectional view, showing a condition where a resist along the line B-B in FIG. 3A is formed by patterning to a predetermined pattern;

FIG. 3C is a cross-sectional view, showing a condition where etching is performed on the region except island portion and an additional capacity portion of the thin film transistor by using the resist prepared by patterning along the line B-B of FIG. 3A as an etching mask;

FIG. 3D is a cross-sectional view, showing a condition where the resist along the line B-B in FIG. 3A is processed by ashing to decrease thickness of the resist film to form an opening on a half-tone exposed portion 302, and a semiconductor island is prepared by etching of a source-drain metal in the lower layer;

FIG. 3E is a cross-sectional view, showing a condition where a photo resist on an upper layer is removed after preparing the semiconductor island along the line B-B in FIG. 3A;

FIG. 4A is a drawing to explain steps in a third photolithographic process in the Embodiment 1 of the invention;

FIG. 4B is a plan view of an essential portion of a pixel region to show a condition where a pixel electrode is formed by the third photolithographic process;

FIG. 4C is a cross-sectional view along the line C-C in FIG. 4B to explain an essential procedure of a process to prepare a pixel electrode;

FIG. 4D is a cross-sectional view subsequent to FIG. 4C along the line C-C in FIG. 4B to explain an essential procedure of the process to prepare the pixel electrode;

FIG. 4E is a cross-sectional view subsequent to FIG. 4D along the line C-C in FIG. 4B to explain an essential procedure of the process to prepare the pixel electrode;

FIG. 5A is a plan view of an essential portion to explain an arrangement of a terminal region in the Embodiment 1 of the invention;

FIG. 5B is a cross-sectional view along the line D-D in FIG. 5A;

FIG. 5C is a cross-sectional view to explain a process subsequent to that of FIG. 5B along the line D-D in FIG. 5A;

FIG. 5D is a cross-sectional view to explain a process subsequent to FIG. 5C along the line D-D in FIG. 5A;

FIG. 5E is a cross-sectional view to explain a process subsequent to FIG. 5D along the line D-D in FIG. 5A;

FIG. 6A is a drawing to explain steps in the third photolithographic process of Embodiment 2 of the invention;

FIG. 6B is a plan view of an essential portion of a pixel region to show a condition where black photo resist is coated in the third photolithographic process and is processed by half-tone exposure;

FIG. 6C is a cross-sectional view along the line E-E in FIG. 6B;

FIG. 6D is a cross-sectional view to explain a process subsequent to that of FIG. 6C along the line E-E in FIG. 6B;

FIG. 6E is a cross-sectional view to explain a process subsequent to that of FIG. 6D along the line E-E in FIG. 6B;

FIG. 6F is a cross-sectional view to explain a process subsequent to that of FIG. 6E along the line E-E in FIG. 6B;

FIG. 7A is a plan view of an essential portion of the active matrix substrate to explain an arrangement of a terminal region in the Embodiment 2 of the invention;

FIG. 7B is a cross-sectional view along the line F-F in FIG. 7A;

FIG. 7C is a cross-sectional view to explain a process subsequent to that of FIG. 7B along the line F-F in FIG. 7A;

FIG. 7D is a cross-sectional view to explain a process subsequent to that of FIG. 7C along the line F-F in FIG. 7A;

FIG. 7E is a cross-sectional view to explain a process subsequent to that of FIG. 7D along the line F-F in FIG. 7A;

FIG. 8 is a drawing to explain steps in the third photolithographic process of Embodiment 3 of the invention;

FIG. 8A is a plan view of an essential portion of a pixel region of active matrix substrate in the Embodiment 3 of the invention;

FIG. 8B is a cross-sectional view along the line U-U in FIG. 8A, showing a condition where the resist is processed by the half tone exposure;

FIG. 8C is a cross-sectional view along the line U-U of FIG. 8A, showing a condition where the resist after patterning in FIG. 8B is processed by ashing;

FIG. 8D is a cross-sectional view along the line U-U in FIG. 8A, showing a condition where ink droplets are pooled within a necessary region by using the resist of FIG. 8C as bank and these are connected to a drain electrode to prepare a pixel electrode;

FIG. 9A is a plan view of an essential portion of a terminal of the active matrix substrate according to the Embodiment 3 of the invention;

FIG. 9B is a cross-sectional view along the line V-V of FIG. 9A, showing a process from the resist coating to the connection of data line and data line terminal;

FIG. 9C is a cross-sectional view along the line V-V of FIG. 9A subsequent to that of FIG. 9B, showing the process from the coating of resist to the connection of the data line with data line terminal;

FIG. 9D is a cross-sectional view along the line V-V of FIG. 9A subsequent to that of FIG. 9C, showing the process from the coating of resist to the connection of the data line with data line terminal;

FIG. 9E is a cross-sectional view along the line V-V of FIG. 9A subsequent to that of FIG. 9D, showing the process from the coating of resist to the connection of the data line with data line terminal;

FIG. 9F is a cross-sectional view along the line W-W in FIG. 9A, showing a process from the coating of resist to the connection of common line with common electrode connection;

FIG. 9G is a cross-sectional view along the line W-W in FIG. 9A subsequent to that of FIG. 9F, showing a process from the coating of resist to the connection of common line with common electrode connection;

FIG. 9H is a cross-sectional view along the line W-W in FIG. 9A subsequent to that of FIG. 9G, showing a process from the coating of resist to the connection of common line with common electrode connection;

FIG. 9I is a cross-sectional view along the line W-W in FIG. 9A subsequent to that of FIG. 9H, showing a process from the coating of resist to the connection of common line with common electrode connection;

FIG. 10A is a drawing to explain photolithographic process of the active matrix substrate to prepare a comb-like common electrode above the pixel electrode in the Embodiment 3 of the invention;

FIG. 10B is a plan view of an essential portion of the pixel region of the active matrix substrate to explain a condition where a common electrode is prepared on the pixel electrode in the Embodiment 3 of the invention;

FIG. 10C is a cross-sectional view along the line X-X in FIG. 10B;

FIG. 10D is a cross-sectional view to explain a process subsequent to that of FIG. 10C along the line X-X in FIG. 10B;

FIG. 11A is a plan view of an essential portion of the terminal of the active matrix substrate to explain a condition where the common electrode is prepared on the pixel electrode in the Embodiment 3 of the invention;

FIG. 11B is a cross-sectional view along the line Y-Y in FIG. 10B to explain a process to form the common electrode on the pixel electrode;

FIG. 11C is a cross-sectional view subsequent to FIG. 11B along the line Y-Y in FIG. 10B to explain a process to form the common electrode on the pixel electrode;

FIG. 11D is a cross-sectional view subsequent to FIG. 11C along the line Y-Y in FIG. 10B to explain a process to form the common electrode on the pixel electrode;

FIG. 11E is a cross-sectional view subsequent to FIG. 11D along the line Y-Y in FIG. 10B to explain a process to form the common electrode on the pixel electrode;

FIG. 12A is a drawing to explain steps in a fourth photolithographic process in the Embodiment 4 of the invention;

FIG. 12B is a plan view of an essential portion of a pixel region on a substrate where the pixel electrode of the Embodiment 4 of the invention is prepared;

FIG. 12C is a cross-sectional view along the line Z-Z in FIG. 12B;

FIG. 12D is a cross-sectional view to explain a process subsequent to that of FIG. 12C along the line Z-Z in FIG. 12B;

FIG. 13A is a cross-sectional view along the line AA-AA in FIG. 12B;

FIG. 13B is a cross-sectional view to explain a process subsequent to that of FIG. 13A along the line AA-AA in FIG. 12B;

FIG. 14A is a drawing to explain steps of a process for preparing a common electrode of the Embodiment 4 of the invention;

FIG. 14B is a plan view of an essential portion of a pixel region of the Embodiment 4 of the invention;

FIG. 14C is a cross-sectional view along the line BB-BB in FIG. 14B;

FIG. 14D is a cross-sectional view to explain a process subsequent to that of FIG. 14C along the line BB-BB in FIG. 14B;

FIG. 15A is a cross-sectional view along the line CC-CC of FIG. 14B;

FIG. 15B is a cross-sectional view to explain a process subsequent to that of FIG. 15A along the line CC-CC in FIG. 14B;

FIG. 16 is a drawing to explain a process of a FFS-COA mode liquid crystal display device to prepare a gate line, a gate electrode and a common line in the Embodiment 5 of the invention and to prepare a color filter and a pixel electrode on a TFT substrate where channel of thin film transistor is formed;

FIG. 17A is a plan view of an essential portion of an image region on an active matrix substrate in the Embodiment 5 of the invention;

FIG. 17B is a cross-sectional view along the line E-E of FIG. 17A;

FIG. 17C is a cross-sectional view to explain a process subsequent to that of FIG. 17B along the line E-E in FIG. 17A;

FIG. 17D is a cross-sectional view to explain a process subsequent to that of FIG. 17C along the line E-E in FIG. 17A;

FIG. 17E is a cross-sectional view to explain a process subsequent to that of FIG. 17D along the line E-E in FIG. 17A;

FIG. 18A is a cross-sectional view along the line G-G in FIG. 17A to explain a process to connect the common electrode with the common line;

FIG. 18B is a cross-sectional view subsequent to FIG. 18A along the line G-G in FIG. 17A to explain a process to connect the common electrode with the common line;

FIG. 18C is a cross-sectional view subsequent to FIG. 18B along the line G-G in FIG. 17A to explain a process to connect the common electrode with the common line;

FIG. 18D is a cross-sectional view subsequent to FIG. 18C along the line G-G in FIG. 17A to explain a process to connect the common electrode with the common line;

FIG. 18E is a cross-sectional view subsequent to FIG. 18D along the line G-G in FIG. 17A to explain a process to connect the common electrode with the common line;

FIG. 19A is a plan view of an essential portion of a terminal of the active matrix substrate in the Embodiment 5 of the invention;

FIG. 19B is a cross-sectional view along the line F-F of FIG. 19A;

FIG. 19C is a cross-sectional view to explain a process subsequent to that of FIG. 19B along the line F-F in FIG. 19A;

FIG. 19D is a cross-sectional view to explain a process subsequent to that of FIG. 19C along the line F-F in FIG. 19A;

FIG. 19E is a cross-sectional view to explain a process subsequent to that of FIG. 19D along the line F-F in FIG. 19A;

FIG. 20 is a drawing to explain a process for preparing a common electrode connection of the active matrix substrate in the Embodiment 5 of the invention;

FIG. 20A is a plan view of a pixel region of the active matrix substrate in the Embodiment 5 of the invention;

FIG. 20B is a cross-sectional view along the line H-H in FIG. 20A;

FIG. 20C is a cross-sectional view to explain a process subsequent to that of FIG. 20B along the line H-H in FIG. 20A;

FIG. 20D is a cross-sectional view along the line J-J in FIG. 20A;

FIG. 20E is a cross-sectional view to explain a process subsequent to that of FIG. 20D along the line J-J in FIG. 20A;

FIG. 21 is a drawing to explain a process for preparing a common electrode of the active matrix substrate in the Embodiment 5 of the invention;

FIG. 21A is a plan view of a comb-like common electrode of the active matrix substrate in the Embodiment 5 of the invention;

FIG. 21B is a cross-sectional view along the line K-K in FIG. 21A;

FIG. 21C is a cross-sectional view to explain a process subsequent to that of FIG. 21B along the line K-K in FIG. 21A;

FIG. 21D is a cross-sectional view along the line L-L in FIG. 21A;

FIG. 21E is a cross-sectional view to explain a process subsequent to that of FIG. 21D along the line L-L in FIG. 21A;

FIG. 22 is a drawing to explain a process for preparing a common electrode on the active matrix substrate in the Embodiment 6 of the invention;

FIG. 23A is a plan view of a pixel region of the active matrix substrate in the Embodiment 6 of the invention;

FIG. 23B is a cross-sectional view along the line M-M in FIG. 23A of the active matrix substrate in the Embodiment 6 of the invention;

FIG. 23C is a cross-sectional view to explain a process subsequent to that of FIG. 23B along the line M-M in FIG. 23A of the active matrix substrate in the Embodiment 6 of the invention;

FIG. 24A is a plan view of a terminal of the active matrix substrate in the Embodiment 6 of the invention;

FIG. 24B is a cross-sectional view along the line N-N in FIG. 23A of the active matrix substrate in the Embodiment 6 of the invention;

FIG. 24C is a cross-sectional view to explain a process subsequent to that of FIG. 24B along the line N-N in FIG. 23A of the active matrix substrate of the Embodiment 6 of the invention;

FIG. 24D is a cross-sectional view to explain a process subsequent to that of FIG. 24C along the line N-N in FIG. 23A of the active matrix substrate of the Embodiment 6 of the invention;

FIG. 24E is a cross-sectional view to explain a process subsequent to that of FIG. 24D along the line N-N in FIG. 23A of the active matrix substrate of the Embodiment 6 of the invention;

FIG. 25 is a drawing to explain a process for preparing a TFT substrate of multi-domain vertical alignment (MVA) mode in the Embodiment 7 of the invention;

FIG. 26A is a plan view to show one-pixel portion of the TFT substrate according to multi-domain vertical alignment (MVA) mode to divide the pixel in slit form of the Embodiment 7 of the invention;

FIG. 26B is a cross-sectional view along the line O-O of FIG. 26A of the TFT substrate in the Embodiment 7 of the invention;

FIG. 26C is a plan view of one pixel to explain an arrangement of another pixel electrode where a protrusion is provided on the pixel of multi-domain vertical alignment (MVA) mode in the Embodiment 7 of the invention;

FIG. 26D is a cross-sectional view along the line P-P in FIG. 26C;

FIG. 26E is a cross-sectional view to explain a process subsequent to that of FIG. 26D along the line P-P in FIG. 26C;

FIG. 27 is a drawing to explain a process for preparing a TFT substrate of multi-domain vertical alignment (MVA-COA) mode with a color filter disposed on the TFT substrate side in the Embodiment 8 of the invention;

FIG. 28A is a plan view to show one-pixel region of the TFT substrate according to multi-domain vertical alignment (MVA) mode where the pixel is divided in slit form in the Embodiment 8 of the invention;

FIG. 28B is a cross-sectional view along the line Q-Q in FIG. 28A;

FIG. 28C is a plan view of one pixel to explain an arrangement of another pixel electrode where a protrusion is provided on the pixel of multi-domain vertical alignment (MVA-COA) mode in the Embodiment 8 of the invention;

FIG. 28D is a cross-sectional view along the line R-R in FIG. 28C;

FIG. 28E is a cross-sectional view to explain a process subsequent to that of FIG. 28D along the line R-R in FIG. 28C;

FIG. 29 is a drawing to explain a third photolithographic process to prepare TFT substrate of multi-domain vertical alignment (MVA-COA) mode with a color filter disposed on the TFT substrate side in the Embodiment 9 of the invention;

FIG. 30A is a plan view of an essential portion of an image region, showing a condition where black color photo resist is coated in the third photolithographic process and the half-tone exposure is performed;

FIG. 30B is a cross-sectional view along the line E-E in FIG. 30A, showing a condition where the third photolithographic process as explained in Step (S-63) of FIG. 29 is carried out;

FIG. 30C is a cross-sectional view to explain a process subsequent to that of FIG. 30B along the line E-E in FIG. 30A;

FIG. 30D is a cross-sectional view to explain a process subsequent to that of FIG. 30C along the line E-E in FIG. 30A;

FIG. 30E is a cross-sectional view to explain a process subsequent to that of FIG. 30D along the line E-E in FIG. 30A;

FIG. 31A is a plan view to show one-pixel region of the TFT substrate on multi-domain vertical alignment (MVA) mode to divide the pixel in slit form in the Embodiment 9 of the invention;

FIG. 31B is a cross-sectional view along the line S-S of FIG. 31A;

FIG. 32A is a plan view of one pixel to explain an arrangement of another pixel electrode where a protrusion is provided on the pixel of multi-domain vertical alignment (MVA-COA) mode with a color filter disposed on the TFT substrate side in the Embodiment 9 of the invention;

FIG. 32B is a cross-sectional view along the line T-T in FIG. 32A;

FIG. 33A is a plan view to show one pixel region of the TFT substrate with the banks where the color filter, the pixel electrode, etc. are prepared are designed in two-layer structure in the arrangement of the pixel electrode with a color filter disposed on the TFT substrate side in the Embodiment 10 of the invention;

FIG. 33B is a cross-sectional view along the line DD-DD in FIG. 33A;

FIG. 33C is a cross-sectional view to explain a process subsequent to that of FIG. 33B along the line DD-DD in FIG. 33A;

FIG. 33D is a cross-sectional view along the line DD-DD in FIG. 33A to explain an arrangement of another pixel electrode where an insulator film is prepared by inkjet on a channel region before the preparation of black color bank in an arrangement of the pixel electrode with a color filter disposed on the TFT substrate side in the Embodiment 10 of the invention;

FIG. 33E is a cross-sectional view to explain a process subsequent to that of FIG. 33D along the line DD-DD in FIG. 33A;

FIG. 33F is a cross-sectional view to explain a process subsequent to that of FIG. 33E along the line DD-DD in FIG. 33A; and

FIG. 34 is a schematical drawing of a liquid crystal display device to explain an example of arrangement of the display device according to the present invention.

### BEST MODE FOR CARRYING OUT THE INVENTION

In the embodiments as described below, the number of the photolithographic processes is reduced by using the patterning of resist bank based on the coating of photo resist and the half-tone exposure, preferably by slit coating method, in the process for preparing the layers of thin film transistors on active substrate of the display device or in the process for forming conductive film such as pixel electrode or common electrode.

### Embodiment 1

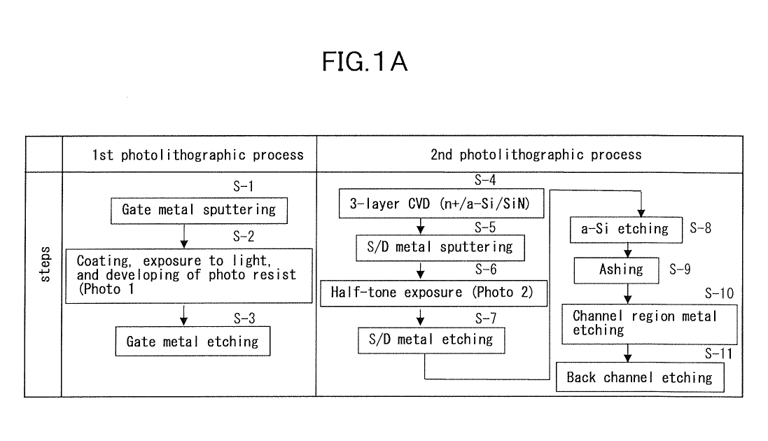

Referring to FIG. 1 to FIG. 5E, description will be given below on an active matrix substrate and on a method of manufacturing the same according to the Embodiment 1 of the invention. The Embodiment 1 is based on the so-called TN mode, and it relates to an active matrix substrate to be used in a liquid crystal display device, which constitutes a certain type of liquid crystal display device where a pixel electrode, i.e. one of the display electrodes, is disposed on the active matrix substrate side, and a counter electrode (common electrode) (i.e. the other of the display electrodes), and a color filter is disposed on the counter substrate side. As the active element, thin film transistor is used. In the following, the active matrix substrate is referred as a thin film transistor substrate, or simply, as a TFT substrate.

FIG. 1 to FIG. 3E are drawings to explain steps of a first photolithographic process and steps of a second photolithographic process in the Embodiment 1 of the invention. The first photolithographic process includes the steps where a gate line and a gate electrode and a storage capacity line (common line) are prepared. The second photolithographic process includes the steps from the preparation of semiconductor islands (active layer islands) to the preparation of channel by etching of data line, source electrode/drain electrode and the back channel. The back channel is a gap on rear surface of a channel region of transistor where etching is removed on an ohmic contact layer (n₊ layer) in gap of source electrode/drain electrode on an upper layer of the semiconductor islands. This ohmic contact layer is electro-conductive, and by performing etching on this layer, the source electrode and the drain electrode are set at opposed positions on the semiconductor, and a transistor channel is formed.

The first photolithographic process comprises:

a step (step 1; hereinafter referred as “step (S-1)”) of performing gate metal sputtering on the gate metal on an insulator substrate (hereinafter simply referred as “substrate”) where ions to contaminate the semiconductor layer are not generated and glass with low thermal expansion coefficient is preferably used;

a step (S-2) where photo resist is coated on the sputtered gate metal, and after processing in masked exposure and developing, the resist is maintained on the regions of the gate line, the gate electrode, and the storage capacity line; and

a step (S-3) where etching is performed, and the gate metals are removed except the regions of the gate line, the gate electrode and the storage capacity line.

The coating of the photo resist in the Step (S-2) may be carried out by the slit coating method, the inkjet method (IJ) or by the spin coating method.

The second photolithographic process comprises:

a step (S-4) for 3-layer CVD film deposition for depositing a gate insulator layer (SiN), a silicon layer (a-Si), and an ohmic contact layer (n⁺) to cover the gate line, the gate electrode and the storage capacity line by CVD in this order;

a step (S-5) of sputtering a metal for source/drain (metal for forming data line, source electrode, and drain electrode) on three-layer CVD film deposition;

a step (S-6) of maintaining the resist on the regions of semiconductor islands, data line, source electrode, and drain electrode after coating the photo resist to cover the metal for source/drain, and after exposing and developing the photo-resist by using the half-tone exposure mask;

a step (S-7) of performing etching on the metal for source/drain by using the remaining resist as an etching mask;

a step (S-8) of performing etching on an ohmic contact layer (n⁺) exposed in the step (S-7) and the silicon layer (a-Si) under it;

a step (S-9) of reducing the thickness of the resist by ashing and preparing an opening on a half-tone exposed region 302 (channel region), and of exposing the metal for source/drain;

a step (S-10) of performing etching on the metal for source/drain exposed to the opening of the half-tone exposed region and of exposing the ohmic contact layer (n⁺); and

a step (S-11) of performing back-channel etching to the ohmic contact layer (n⁺) exposed to the opening of the half-tone exposed region.

It is needless to say that the processing is carried out by changing the condition of etching such as etchant in these steps of etching as described above. As a general type etching, wet etching is performed for metal, and dry etching is adopted for the silicon layer and the ohmic contact layer (n⁺).

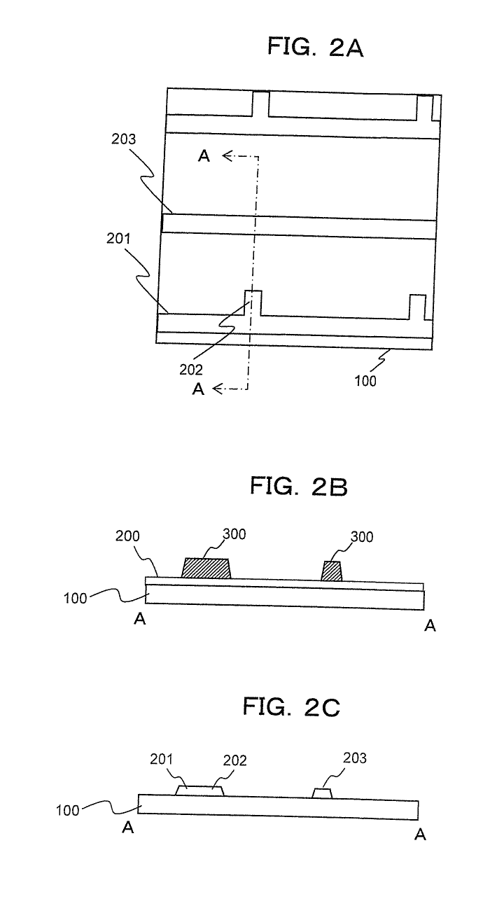

FIG. 2A is a plan view of an essential portion to explain the patterning of the gate line and the gate electrode, which are prepared in the first photolithographic process shown in FIG. 1A. Each of FIG. 2B and FIG. 2C represents a cross-sectional view along the line A-A in FIG. 2A to explain an essential part of the process to prepare the gate line and the gate electrode. FIG. 2B shows a condition where patterns of the resist for the gate line and the gate electrode are prepared by patterning, and the pattern of the resist 300 of the storage capacity line is formed on a gate metal 200 sputtered on the substrate 100. FIG. 2C shows a condition where etching is performed on the gate metal 200 using the resist 300 as a mask, and a gate line 201, a gate electrode 202 and a storage capacity line 203 are prepared by removing the resist 300.

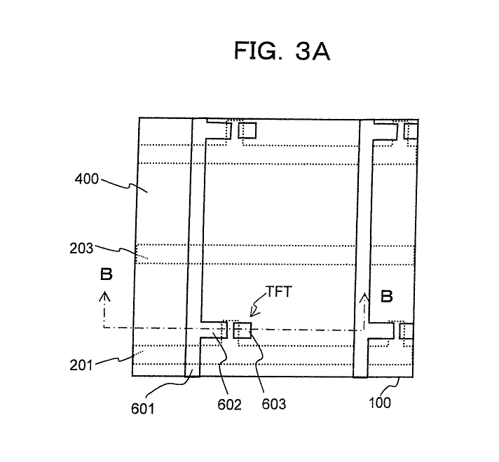

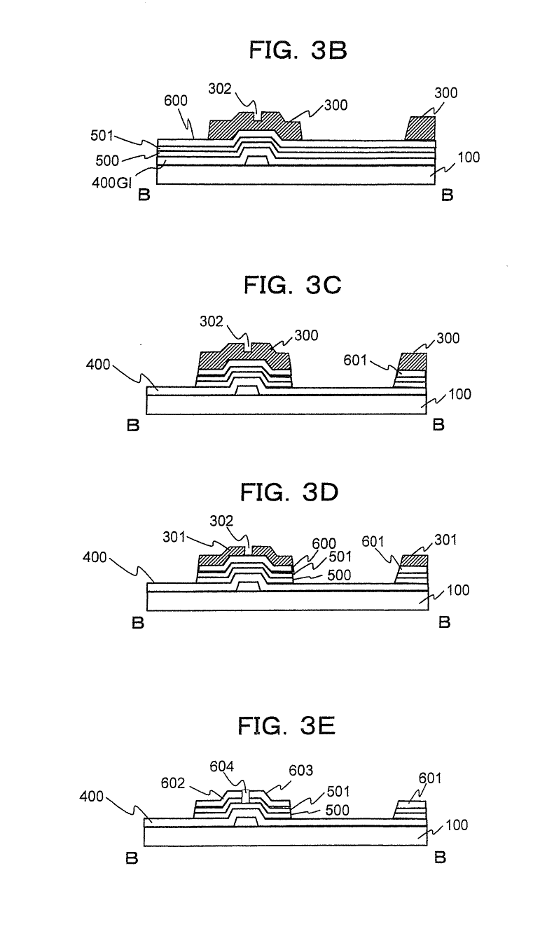

FIG. 3A is a plan view of an essential portion of an active matrix substrate to explain a thin film transistor, a data line, a source electrode and a drain electrode prepared in the second photolithographic process of FIG. 1A. In a region enclosed by two gate lines 201 and two data lines 601, one unit pixel (a sub-pixel, which is a color pixel in case of color display) is formed.

Each of FIG. 3B to FIG. 3E represents a cross-sectional view along the line B-B in FIG. 3A to explain an essential part of the process to prepare the thin-film transistor, the data line, the source electrode and the drain electrode. In FIG. 3B, a gate insulator film (SiN) 400, a silicon layer (a-Si) 500, and an ohmic contact layer (n⁺) 501 are deposited in this order by CVD to cover the gate line 201, the gate electrode 202 and the storage capacity line 203 as shown in FIG. 2A (3-layer CVD film deposition). On it, a source/drain metal (S/D metal), which is to be a source line, a source electrode and a drain electrode, is deposited by sputtering. Further, a photo resist is coated by using a slit coater (an inkjet device may be used) on it, and it is dried to have a photo resist layer 300. This photo resist layer 300 is exposed to light via an exposure mask, which has a half-tone opening on a part of it. The half-tone exposed region 302 is disposed at a position where the channel of the thin film transistor is formed. Then, a gap along the line B-B of the half-tone exposed region 302 will be a channel width.

In this exposure process, a negative type photo resist is used, and it is so designed that the total layer of the photo resist of the fully exposed portion (full-exposure region) is solubilized, and the portion of shadow formed by the exposure mask is not soluble in the developing solution. The exposure mask is so arranged that it has a pattern of such light transmittance, which will be lower than the full-exposure portion, or it is designed as an opening pattern so that the exposure amount is reduced by interference of light, and solubilization reaction of the photo resist on that portion is hindered. The light quantity of the half-tone exposed region is determined by the relation with the resist loss quantity at the time of ashing as to be described later. It may be so arranged that, by using the photo resist of positive type, the half-tone exposure as necessary may be performed in combination with the exposure mask, which has reverse exposure characteristics. FIG. 3B shows a condition where the resist is processed to the pattern as required by patterning.

In FIG. 3C, etching is performed on island region and data line region of the thin film transistor by using the resist processed by patterning as an etching mask. In this processing, etching is performed on the source/drain metal (S/D metal), which will be the data line, the source electrode and the drain electrode (Step S-7). Further, etching is performed on the silicon layer (a-Si) 500 subsequent to the ohmic contact layer (n⁺) 501. In the etching of the source/drain metal (S/D metal) 600, the ohmic contact layer (n⁺) 501 and the silicon layer (a-Si) 500, an etchant suitable for each of these layers is used.

In FIG. 3D, the resist 300 is processed by ashing, and the resist film is reduced in thickness. Then, the half-tone exposed region 302 is opened, and the source/drain metal 600 of the lower layer is exposed (Step S-9). Etching is performed on the source/drain metal 600 of the exposed channel portion (Step S-10). Next, the ohmic contact layer (n⁺) 501 is etched (etching of back channel: Step S-11). Finally, the resist is removed. This condition is shown in FIG. 3E. The above is the description of the first photolithographic process and the second photolithographic process according to the present invention.

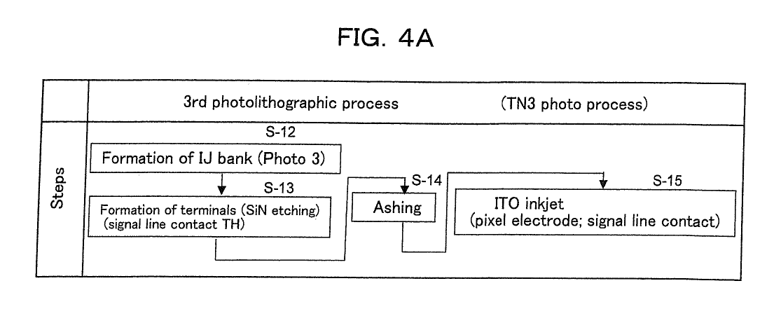

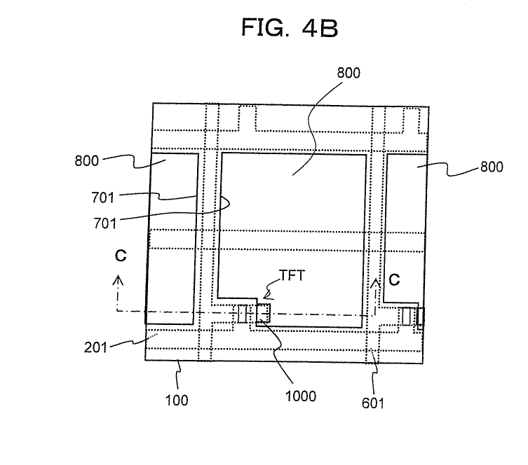

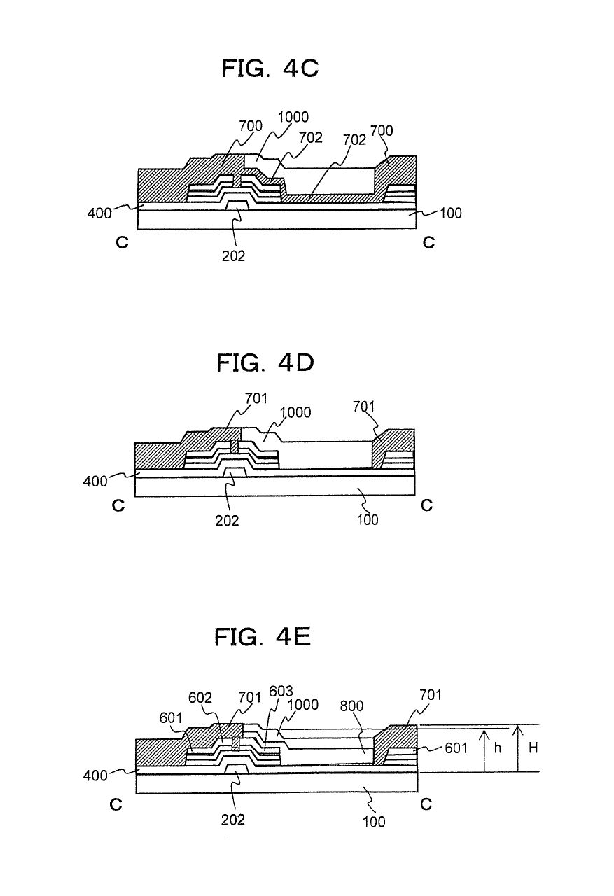

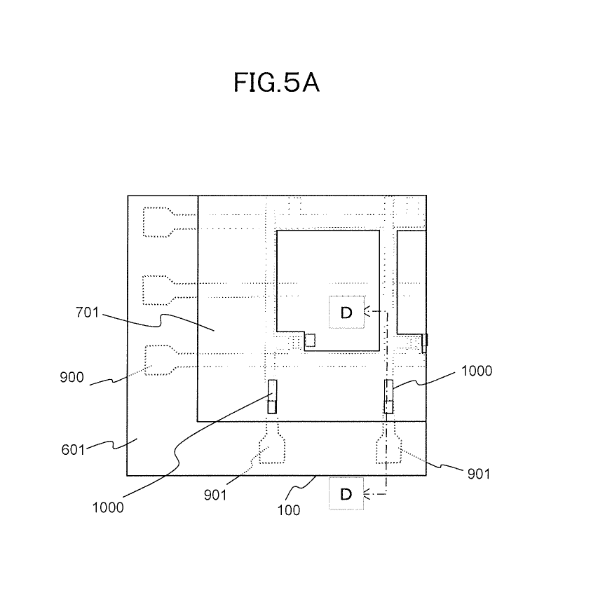

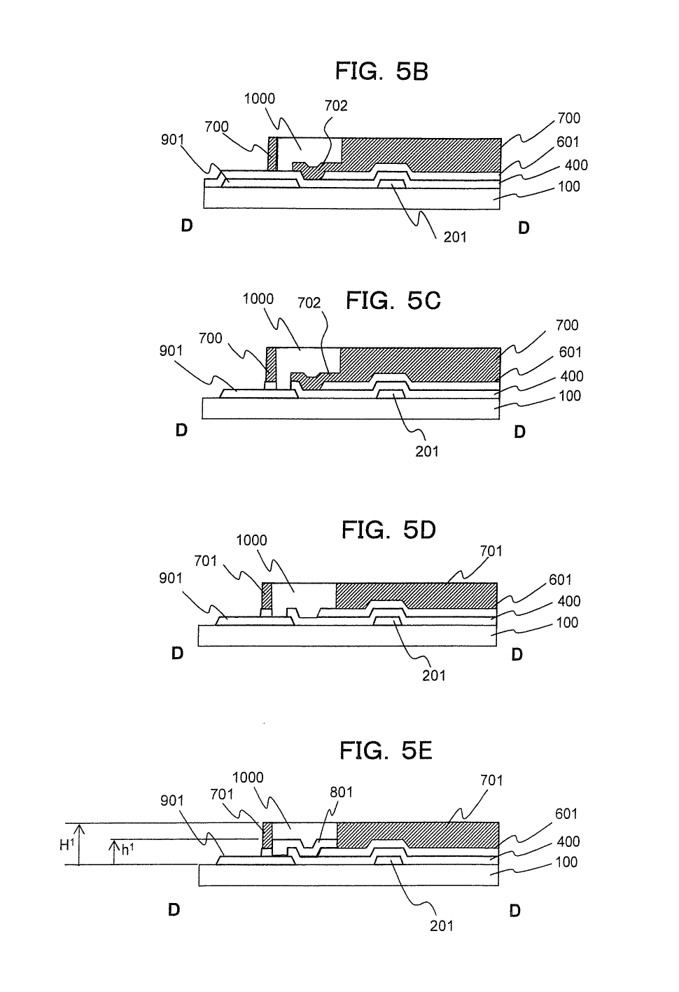

Each of FIG. 4A to FIG. 5E is to explain the third photolithographic process of the Embodiment 1 of the invention. FIG. 4A is to explain the steps of the third photolithographic process of the Embodiment 1 of the invention. Photo resist is coated on the thin film transistor substrate shown in FIG. 3E by a slit coater. Then, by using half-tone exposure mask, the pixel region and a contact hole to connect the pixel electrode, as one of the display electrodes, to the drain electrode is processed by the half-tone exposure. The terminal of the gate line and the terminal of the data line are processed by full-exposure, and banks are prepared around the pixel electrode (Step S-12). This step (S-12) is the third photolithographic process.

Using this resist as the mask, the terminal of the gate line and the terminal of the data line are exposed (Step S-13). Then, the resist is processed by ashing, and the resists on the pixel region and the contact hole are removed (Step S-14). The pixel region and the contact hole are enclosed by the banks of resist. Inside the banks, an ink containing a transparent conductive film material dispersed in it (ITO is preferable to use) is dropped inside the banks, and it is coated (Step S-15). Then, the ink film is baked, and a pixel electrode is connected to the thin film transistor.

FIG. 4B is a plan view of an essential portion of the pixel region, showing a condition where the pixel electrode is prepared in the third photolithographic process of the Embodiment 1 of the invention. The pixel electrode 800 is connected to the drain electrode of the thin film transistor TFT via a contact hole 1000. Being connected to the drain electrode of the thin film transistor TFT at the contact hole 1000, the pixel electrode 800 is disposed inside the bank 701, which is formed above two gate lines 201 and two data lines.

Each of FIG. 4C to FIG. 4E represents a cross-sectional view along the line C-C in FIG. 4B to explain an essential part of the process to prepare the pixel electrode. In FIG. 4C, the photo resist is coated by a slit coater on the thin film transistor shown in FIG. 3E. By using the half-tone exposure mask, the contact hole connecting the pixel region and the pixel electrode to the drain electrode is processed by the half-tone exposure. The terminal of the gate line and the terminal of the data line are processed by full exposure, and banks are disposed around the pixel electrode. This is the condition of the third photolithographic processing as explained in Step (S-12) shown in FIG. 4A. In this third photolithographic processing, the resist film is thinner because of the half-tone exposure on the pixel region and the contact hole 100. Numeral 702 represents the resist, which is thinner on the half-tone exposed region. The resist 702 on the half-tone exposed region is enclosed by the thick resist 700.

FIG. 4D shows a condition where the resist film 700 and the resist 702 on the half-tone exposed region are processed by ashing and the thickness is reduced. By the ashing, the resists on the pixel region and the contact hole are removed. The film thickness of the remaining resist 701 is somewhat thinner by an extent of the resist 702 of the half-tone exposed region or is slightly thinner.

FIG. 4E shows a condition where an ink containing a transparent conductive material (preferably ITO) dispersed in it is dropped inside the banks for preparing pixel formed by the resist 701 by inkjet method, and a pixel electrode 800 made of transparent conductive film is prepared. The pixel electrode 800 is connected to the drain electrode 603 of the thin film transistor via the contact hole 1000. A height “h” of upper surface of the transparent conductive film from the substrate 100 to cover the drain electrode 603 is lower than a height “H” of upper surface of the bank to prepare the pixel formed by the resist 701 from the substrate 100. (The height h is lower than the height H.) The same applies to the other embodiments as described below.

FIG. 5A is a plan view of an essential portion to explain an arrangement of the terminal region in the Embodiment 1 of the invention. FIG. 5A is a plan view to correspond to FIG. 58 (to be given later) where the terminal region is covered by the gate insulator film 601. Each of FIG. 5B to FIG. 5E represents a cross-sectional view along the line D-D in FIG. 5A.

FIG. 5B shows a condition where the thickness of the resist film 700 processed by the half-tone exposure is reduced at the contact hole 1000, which connects the data line with the terminal 901. FIG. 5C shows a condition where etching is removed from the gate insulator film 601 by using the half-tone exposure resist 702 as an etching mask. FIG. 5D shows a condition where the thickness of the resist film is reduced by ashing, and it is shown that the resist on the contact hole 1000 is removed and the data line 601 is exposed.

FIG. 5E shows a condition where an ink containing a transparent conductive material (preferably ITO) dispersed in it is dropped by inkjet method to the contact hole 1000 and is coated on it, and this is prepared as a terminal connection 801. The data line is connected to the terminal 901 via this terminal connection 801. A height “h′” of upper surface of the terminal connection 801 from the substrate 100 is lower than a height “H′” of upper surface of the terminal connection 801 from the substrate 100. (The height h′ is lower than the height H′.) The same applies to the other embodiments to be described below. Here, ITO (i.e. the same material as the pixel electrode 800) is preferable as the material to be dropped and coated on the contact hole 1000, while any material may be used, which has electro-conductive property and has lower contact resistance with the data line 400 and the terminal 901. For instance, Ni, Mo, W, etc. may be used.

In the Embodiment 1 of the invention as described above, by reducing the number of photolithographic processes, the active matrix substrate can be manufactured by reducing the number of processes as a whole, and a TN mode liquid crystal display device can be offered at relatively lower price.

### Embodiment 2

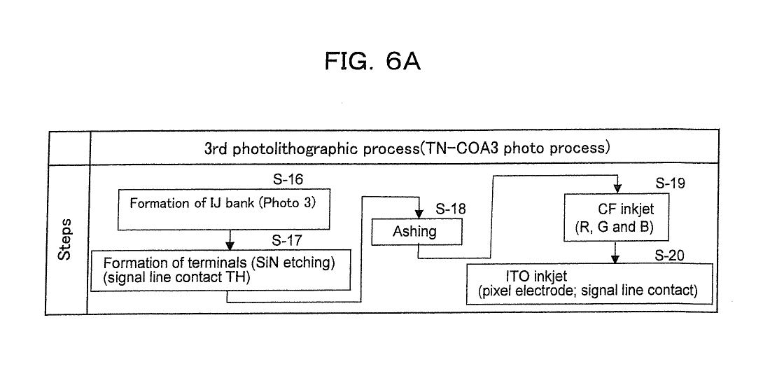

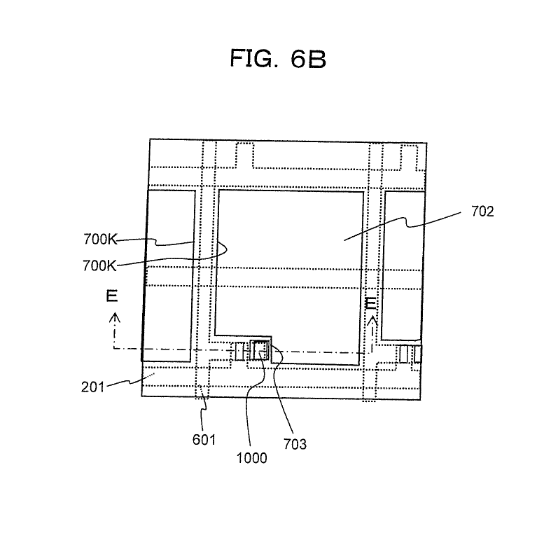

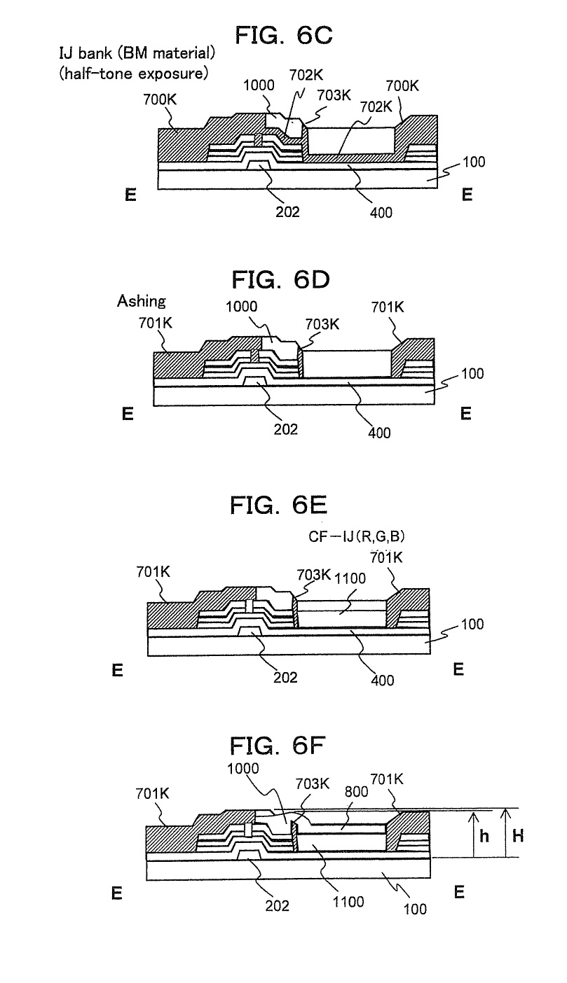

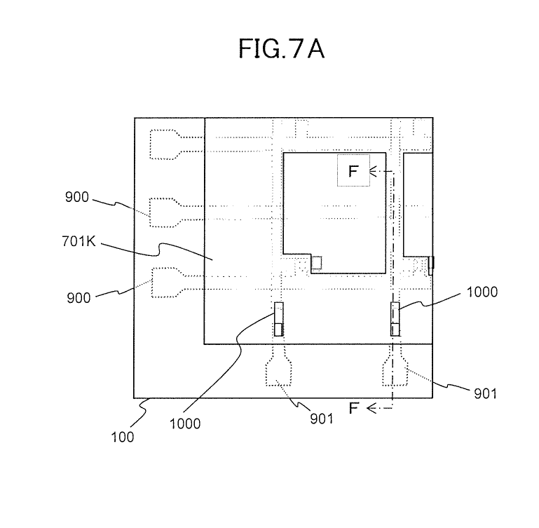

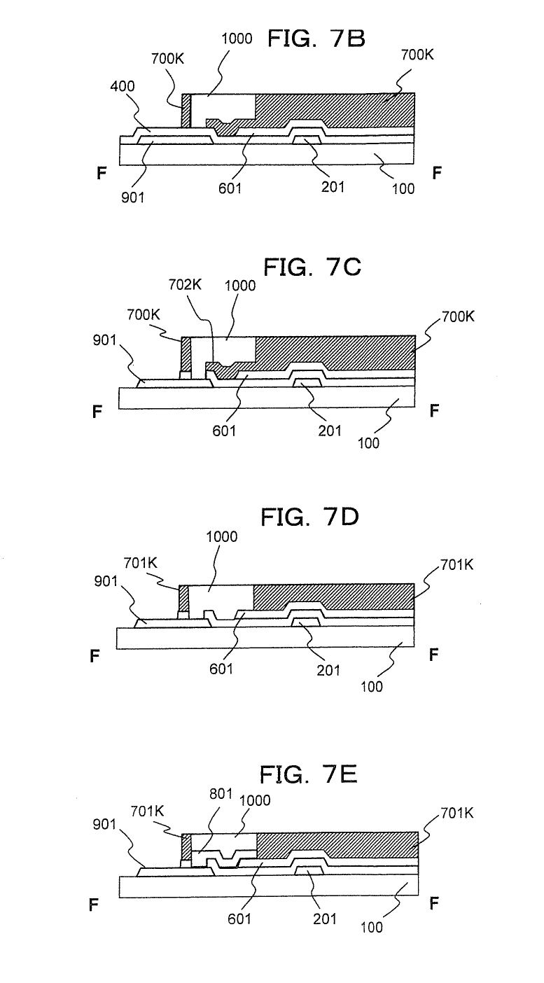

Referring to FIG. 6A to FIG. 6F and FIG. 7A to FIG. 7E, description will be given below on the active matrix substrate and the method of manufacturing it in the Embodiment 2 of the invention. The Embodiment 2 relates to a TN type liquid crystal display device of color filter on array (TN-COA) mode, which has the so-called TN type liquid crystal display device with a color filter disposed on the active matrix substrate. Similarly to the Embodiment 1, the thin film transistor is used as active matrix. In the following, description will be given on the active matrix substrate as a thin film transistor (TFT) substrate.

The first photolithographic process and the second photolithographic process in the Embodiment 2 are the same as those described in connection with FIG. 1A to FIG. 3E of the Embodiment 1, and detailed description is not given here. The details of the third photolithographic process, which is the special features of the Embodiment 2, will be described below.

FIG. 6A is a drawing to explain the steps in the third photolithographic process of the Embodiment 2. A black color photo resist with a black color material intermingled in it is coated on the thin film transistor substrate shown in FIG. 3E by using a slit coater. A contact hole to connect a pixel region and a pixel electrode to a drain electrode is processed by the half-tone exposure by using a half-tone exposure mask, and the terminal of the gate line and the terminal of the data line are processed by full-exposure, and banks of black color photo resist (may be referred simply as “black color resist”) are prepared around the pixel electrode (Step S-16). This step (S-16) is the third photolithographic process.

A ridge of the black color resist prepared under non-exposure is provided between a region with the pixel electrode and the contact hole for connecting the pixel electrode and the drain electrode of the thin film transistor. This ridge is to prevent overflow of the color filter ink coated by inkjet method before coating the inkjet on the pixel electrode.

By using the resist as a mask, the terminal of the gate line and the terminal of the data line are exposed (Step S-17). Then, after processing the resist by ashing, the resist on the pixel region and the contact hole are removed (Step S-18). The pixel region and the contact hole are enclosed by the banks of black color resist. The ridge as described above is positioned between the region of the pixel electrode and the contact hole.

An ink containing a color filter material of one of the predetermined colors (i.e. one of R, G, or B) is coated by inkjet method inside the banks and on a side of the ridge closer to the pixel electrode (Step S-19). The ink of the color filter is prevented from leaking out to the contact hole by the ridges as described above. The banks of the black color resist surrounds the pixel and fulfills the function as a black matrix. Then, this ink film is baked, and a color filter is prepared.

An ink containing a transparent conductive material (preferably ITO) dispersed in it is dropped and is coated so that it goes over an upper layer of the color filter and over the ridge to reach the contact hole (Step S-20). Then, this ink film is baked, and a pixel electrode as one of the display electrodes connected to the drain electrode of thin film transistor is prepared.

Here, the baking of the color filter and the baking of the pixel electrode were performed separately, while the color filter may be baked at such low temperature that no problem occurs for the preparation of the ink film for preparing the pixel electrode, and the baking operation may be carried out at the same time.

FIG. 6B is a plan view of an essential portion of the pixel region where black color photo resist is coated in the third photolithographic process and the condition processed by the half-tone exposure is shown. The region processed by the half-tone exposure includes a region where the pixel electrode is prepared as one of the display electrodes (the color filter is coated on lower layer of the pixel electrode) and the region of the contact hole. As shown in FIG. 6B, the contact hole 1000 is separated by the ridge 703 from the region where the pixel electrode is formed.

Each of FIG. 6C to FIG. 6F is a cross-sectional view along the line E-E in FIG. 6B. FIG. 6C shows a condition where the third photolithographic processing as explained in the Step (S-16) is performed. That is, a black color photo resist 700K is coated by inkjet method on the thin film transistor substrate. The contact hole for connecting the pixel region and the pixel electrode to the drain electrode is processed by the half-tone exposure by using a half-tone exposure mask, and the terminal of the gate line and the terminal of the data line are processed by full-exposure, and black color banks are disposed around the pixel electrode (Step S-16). In this third photolithographic process, the pixel region and the contact hole 1000 are processed by the half-tone exposure, and the resist film is thinner. The black color resist processed by the half-tone exposure is represented by 702K. The resist 702K processed by the half-tone exposure is surrounded by a thick black color resist 700K.

FIG. 6D shows a condition where the black color resist film 700K and the black color resist 702K processed by the half-tone exposure are processed by ashing to reduce the thickness. By ashing, the resists on the pixel and on the contact hole are removed. Film thickness of the remaining black color resist 701K is reduced in an extent to correspond to the reduced thickness of the black color resist 702K on the removed half-tone exposed region or slightly thinner than that.

FIG. 6E shows a condition where a color filter ink 1100 is coated on a region inside the banks for forming the pixel as prepared by the black color resist 701K. As shown in FIG. 6F, an ink containing a transparent conductive material (preferably ITO) dispersed in it is dropped to and coated on the color filter 1100 and over the ridge 703K to the contact hole 1000, and the pixel electrode 800 is prepared. The pixel electrode 800 is connected to the drain electrode 603 of the thin film transistor via the contact hole 1000.

FIG. 7A is a plan view of an essential portion of the active matrix substrate to explain an arrangement of the terminal in the Embodiment 2 of the invention. FIG. 7A is a plan view of the active matrix substrate, which corresponds to the one shown in FIG. 7B, in which the terminal is covered with a gate insulator film 601. Each of FIG. 7B to FIG. 7E is a cross-sectional view along the line F-F in FIG. 7A.

FIG. 7B shows that the thickness of the black color resist film 700K processed by the half-tone exposure is reduced in the region of the contact hole 1000, which connects the data line and its terminal 901. FIG. 7C shows a condition, in which etching of the gate insulator film 400 is removed by using the black color resist film 700K and the resist 702K processed by the half-tone exposure. FIG. 7D shows a condition where the thickness of the black color resist is reduced by ashing, and the black color resist in the contact hole 100 is removed and the data line 601 is exposed.

FIG. 7E shows a condition where an ink containing a transparent conductive material (preferably ITO) dispersed in it is dropped to and coated on the contact hole 1000, and the data line 601 is connected to the terminal 901 via a terminal connection 801. Here, it is described that ITO, which is the same material as that of the pixel electrode 800, is preferable as a material to be coated on the contact hole 1000, while any material may be used, which has electro-conductive property and has low contact resistance to the data line 400 and the terminal 901. For instance, Ni, Mo, W, etc. may be used. The same applies in the embodiments to be described hereinafter.

In the Embodiment 2 of the invention as described above, by reducing the number of photolithographic processes, it is possible to manufacture the active matrix substrate by smaller number of processes, and a liquid crystal display device can be offered at inexpensive manufacturing cost as a whole. Also, by preparing the color filter on the TFT substrate side, numerical aperture can be improved without taking alignment tolerance with the counter substrate into account. As a result, it is possible to reduce power consumption required for the manufacture of the liquid crystal display device, to adopt plastic substrate with higher light transmittance, and to produce a TN type liquid crystal display device of color filter on array mode using plastic substrate by reducing the material cost.

### Embodiment 3

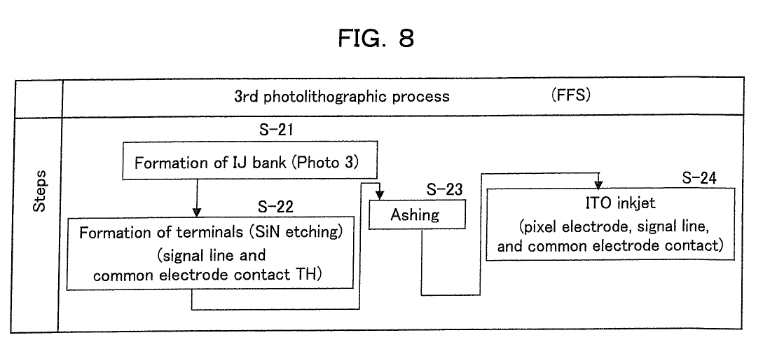

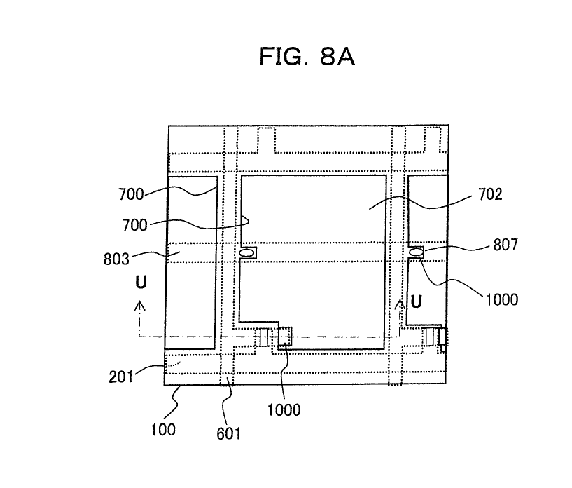

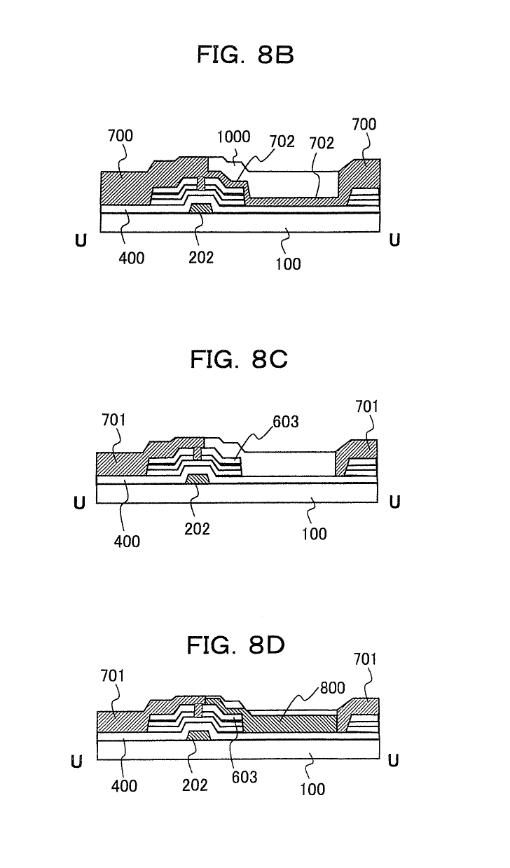

Now, referring to FIG. 8 to FIG. 11E, description will be given on the action matrix substrate and the method to manufacture it in the Embodiment 3 of the invention. The Embodiment 3 relates to an active matrix substrate for liquid crystal display device of the so-called FFS (Fringe Field Switching) type. In the Embodiment 3, the procedures of the first photolithographic process to prepare the gate line, the gate electrode and the additional capacity line (common line) on the substrate and the second photolithographic process to prepare channel of the thin film transistor are the same as the procedures in the Embodiments 1 and 2 as described above, and detailed description is not given here. Here, description is started from the description on the third photolithographic process of the Embodiment 3. In the first photolithographic process, the common line is prepared at the same time as the gate line and the gate electrode, while the common line may be regarded as the same as that of the additional capacity line in the Embodiments 1 and 2.

FIG. 8 is a drawing to explain the steps in the third photolithographic process in the Embodiment 3 of the invention. On the substrate prepared in the second photolithographic process, a photo resist is coated by a slit coater. This photo resist is processed by using a half-tone exposure mask, and banks (IJ banks) are prepared by patterning (Step S-21).

The gate insulator film is removed by etching, and a contact hole 1000 for connecting the gate line terminal 900 with the common line terminal 902 and the data line terminal 901 and the contact hole 1000 for connecting the data line terminal, and a contact hole 1000 is prepared on a common electrode connection of the common line, and wiring or electrode on lower layer is exposed (Step S-22). The thickness of the resist is reduced by ashing (Step S-23). Inside the banks formed by the resist, an ink containing ITO as a transparent conductive film is dispersed it, and it is coated by inkjet method. As a result, ITO is embedded in the pixel electrode and the contact holes, and the electrodes for connection are prepared (Step S-24).

FIG. 8A is a plan view of an essential portion of an image region of the active matrix substrate according to the Embodiment 3 of the invention. One unit pixel (each of color pixel in case of color display; sub-pixel) is formed on a region surrounded by two gate lines 201 and two data lines 601 on the substrate 100. FIG. 8A shows a condition where the resist is processed by the half-tone exposure and is developed, and banks 700 are prepared. The region where the pixel electrode is prepared and the contact hole for connecting the pixel electrode to the drain electrode of the thin film transistor are processed by the half-tone exposure and thin resist film 702 is formed. The common line 803 is prepared on the central portion of pixel in a direction parallel to the gate line 201. In the region where the pixel electrode is prepared, a part of the bank is protruded above the common line 803, and a common electrode connection 807 is formed, and the contact hole 1000 is disposed on the common electrode connection 807.

FIG. 8B is a cross-sectional view long the line U-U of FIG. 8A. A thin film transistor array is prepared on the substrate 100. Photo resist is coated on it and light exposure is performed by using a half-tone exposure mask. By developing it, the resist comprising a non-exposed portion 700 and a half-tone exposed portion 701 are prepared by patterning. In the non-exposed portion, the resist is thick, while film thickness of the resist is thin on the half-tone exposed portion 701.

FIG. 8C is a cross-sectional view along the line U-U in FIG. 8A, showing a condition where the resist prepared by patterning is processed by ashing. By this ashing processing, the thickness of the resist is decreased, and the resist 701 on the half-tone exposed portion is removed. As a result, the gate insulator film 400 on the region where the pixel electrode is formed is exposed, and the drain electrode 603 is exposed on the contact hole 1000. An ink containing a transparent conductive material (preferably ITO) dispersed in it is coated on the exposed gate insulator film 400 and on the contact hole 1000 to cover the drain electrode 603, and a pixel electrode 800 connected to the drain electrode 603 of the thin film transistor is prepared. When the inkjet is coated, the resist 701 plays a role of a bank, and ink droplets are pooled within the region as necessary. This condition is shown in FIG. 8D.

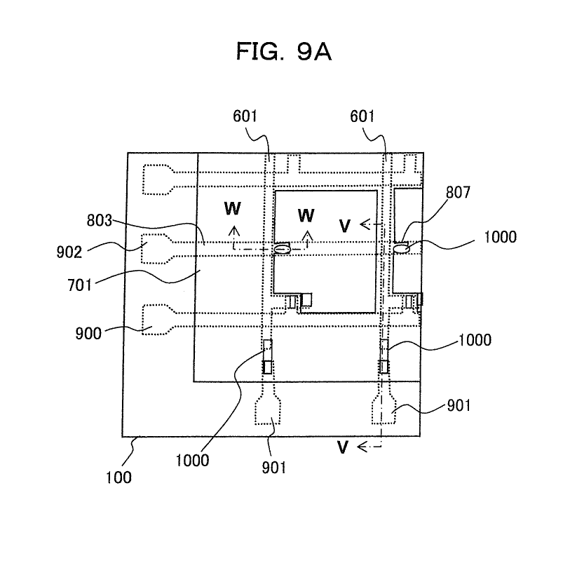

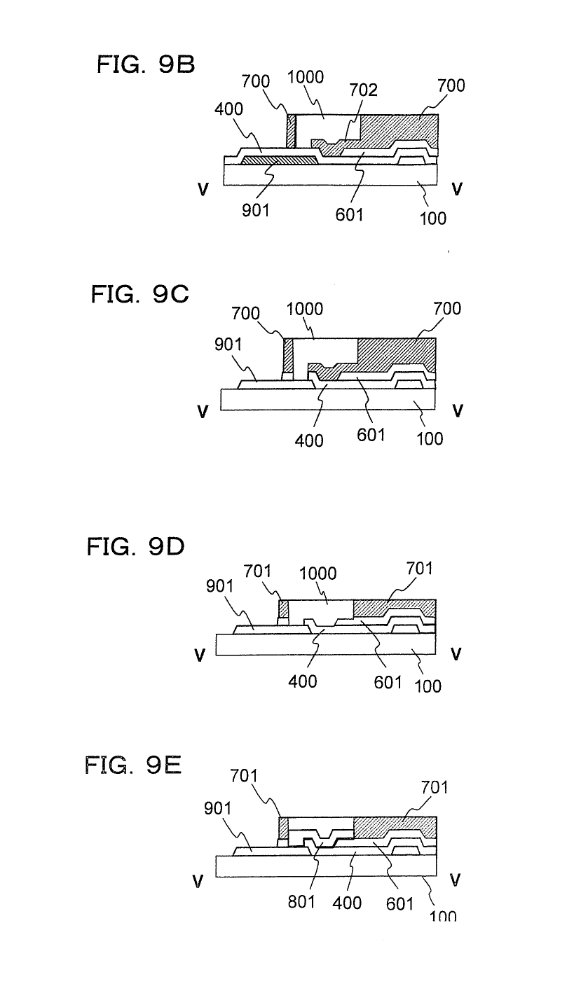

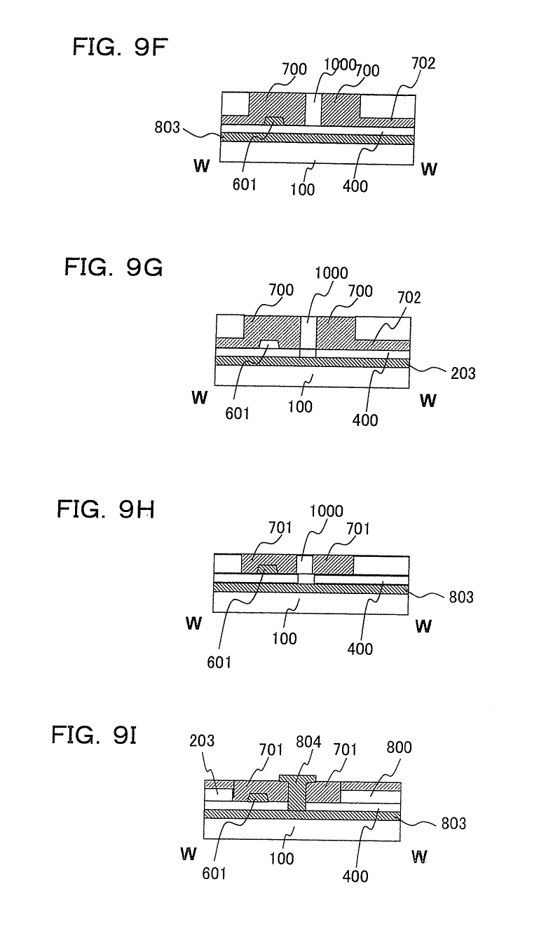

FIG. 9A is a plan view of an essential portion of the terminal of the active matrix substrate according to the Embodiment 3 of the invention. On the terminal of the active matrix substrate, a gate line terminal 900, a data line terminal 901, and a common line terminal 902 are disposed. The bank 701 (FIG. 9D) of the resist has the common electrode connection 807, which protrudes to the region where the pixel is prepared above the common line 803. A contact hole 1000 is provided for forming a common electrode connecting electrode 804 (FIG. 9I) where the common electrode is to be connected with the common line 80 as the other of the display electrodes.

Each of FIG. 9B to FIG. 9I is a cross-sectional view along the line V-V of FIG. 9A, showing the processes from the coating of the resist to the connection of the data line with the data line terminal. FIG. 9B shows a condition where the resist 700 is coated and is exposed to light by using the half-tone exposure mask, and then, it is developed and processed by patterning. Numeral 702 denotes the resist in the half-tone exposed region. Etching is performed on the gate insulator film 400 by using this resist pattern as an etching mask, and the region of the data line terminal 901 and the contact hole 1000 are exposed. This is shown in FIG. 9C.

FIG. 9D shows a condition where the resist on the half-tone exposed region is removed by ashing of the resist, and the data line 601 is exposed. Then, an ink containing ITO dispersed in it is coated by inkjet method, and a terminal connection 801 is prepared. This condition is shown in FIG. 9E.

FIG. 9F is a cross-sectional view along the line W-W in FIG. 9A, showing the processes from the coating of the resist to the preparation of the common electrode connecting electrode. The resist 70 is coated and light exposure is performed using the half-tone exposure mask. Then, a half-tone exposed region 702 is prepared, and this is developed and is processed by patterning. On a part of the common line 803, a contact hole 1000 as explained in connection with FIG. 8A and FIG. 9A is formed. The gate insulator film 400 on the contact hole 1000 is processed by etching, and a common line 803 immediately below is exposed. This is shown in FIG. 9G.

FIG. 9H shows a condition where ashing is performed on the resist, and it is shown that the full-exposed portion is the resist film 701, which has its thickness reduced by ashing in the full-exposed portion. As shown in FIG. 9H, an ITO-dispersed ink is coated on the contact hole 1000 by inkjet coating, and a common electrode connecting electrode 804 is prepared. This is shown in FIG. 9H. The coating of the ITO-dispersed ink is performed at the same time as the preparation of the terminal connecting electrode and the pixel electrode as described above.

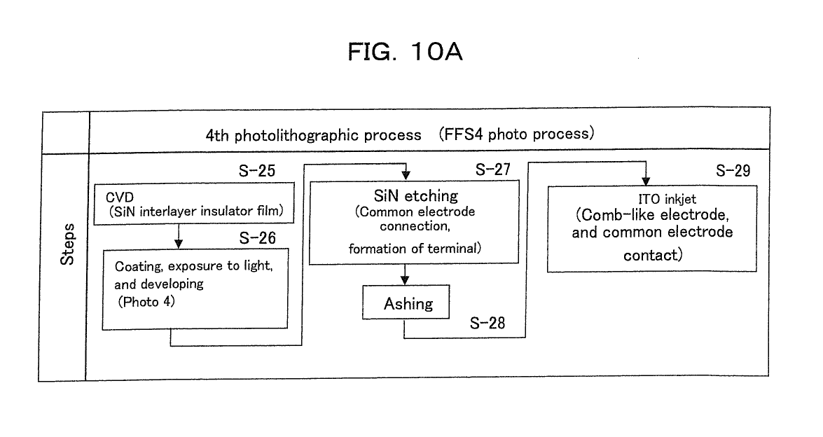

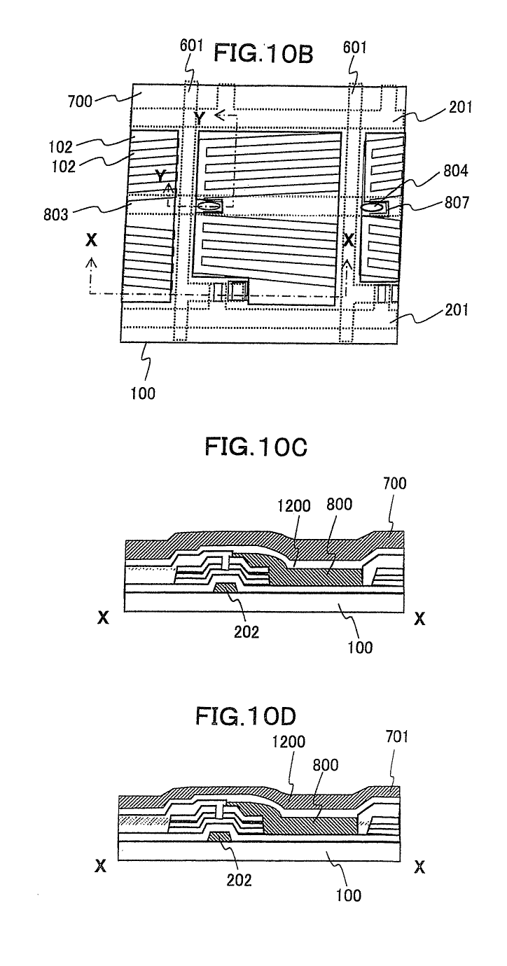

FIG. 10A is a drawing to explain the photolithographic process of the active matrix substrate where a comb-like common electrode is disposed above the pixel electrode according to the Embodiment 3 of the invention. In FIG. 10A, an interlayer insulator film is deposited by CVD on the active matrix substrate as shown in FIG. 8D, FIG. 9E and FIG. 9I (Step S-25). Silicon nitride (SiN) is used on the interlayer insulator film, but it is not limited to SiN. Photo resist is coated on the interlayer insulator film by a slit coater, and light exposure is performed by using a half-tone exposure mask. This is developed and the resist pattern is formed (Step S-26).

Etching is performed on the interlayer insulator film by using this resist pattern as an etching mask, and the common electrode connection and the terminal are exposed (Step S-27). Next, ashing is performed on the resist, and the resist on the half-tone exposed portion is removed (Step S-28), and an ink containing a transparent conductive material (preferably ITO) dispersed in it is coated by inkjet coating (Step S-29). The ITO ink is pooled in the bank of the resist. Then, this ink film is baked and a comb-like common electrode connected to the common line is prepared.

FIG. 10B is a plan view of an essential portion of the pixel region of the active matrix substrate to explain a condition where the common electrode is prepared on the pixel electrode. On the substrate 100, a comb-like common electrode 805 is disposed via the interlayer insulator film 1200. The common electrode 805 is connected to the common line 803 via the common electrode connecting electrode 804.

Each of FIG. 10C and FIG. 10D is a cross-sectional view along the line X-X of FIG. 10B. The interlayer insulator film (SiN) 1200 is deposited on the substrate as explained in connection with FIG. 8A and FIG. 9A. Further, a photo resist 700 is coated on it, and it is processed by the half-tone exposure method using a half-tone exposure mask. After developing, the common electrode connection and the comb-like common electrode pattern are formed. Ashing is performed on the resist as shown in FIG. 10D, and banks to enclose the pixel region and the contact hole are prepared. As a result, the comb-like resist pattern 701 penetrates the interlayer insulator film 1200 on lower layer.

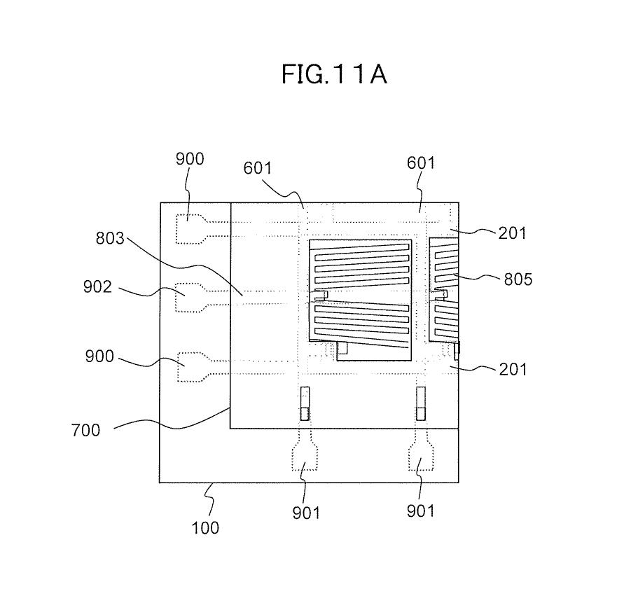

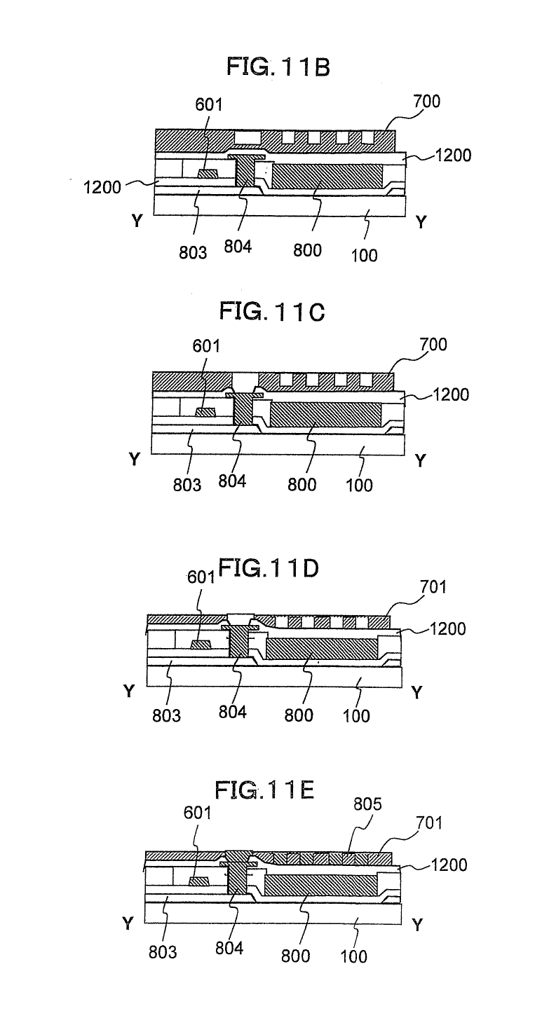

FIG. 11A is a plan view of an essential portion of the terminal of the active matrix substrate to explain a condition where a common electrode is formed on the pixel electrode. A comb-like common electrode 805 is prepared on the substrate 100 via the interlayer insulator film. The common electrode 805 is connected to the common line 803 via the common electrode connecting electrode 804.

Each of FIG. 11B to FIG. 11E is a cross-sectional view along the line Y-Y in FIG. 10B to explain the processes to form a common electrode on the pixel electrode. In FIG. 11B, a photo resist 700 is coated on the interlayer insulator film 1200, and a comb-like resist pattern is formed by using the half-tone exposure mask. In FIG. 11C, etching is removed from the common electrode connection, the gate line terminal, the common line terminal and the interlayer insulator film 1200 of the data line terminal by using the resist pattern as an etching mask.

The comb-like resist pattern is processed by the half-tone exposure. As shown in FIG. 11D, ashing is performed on the resist, and the opening of the common electrode preparing region of the comb-like resist pattern is penetrated into the interlayer insulator film 1200. To the common electrode preparing region and to the opening on the common electrode connecting electrode 804, an ink containing a transparent conductive material (preferably ITO) dispersed in it is coated by inkjet method, and the comb-like common electrode 805 is prepared. Then, the common electrode connecting electrode 804 is connected to the common electrode 805. This is shown in FIG. 11E.

According to the Embodiment 3 as described above, by reducing the number of photolithographic processes, the active matrix substrate and the liquid crystal display device can be manufactured by reducing the number of processes as a whole, and the FFS type liquid crystal display device can be manufactured at lower cost.

### Embodiment 4

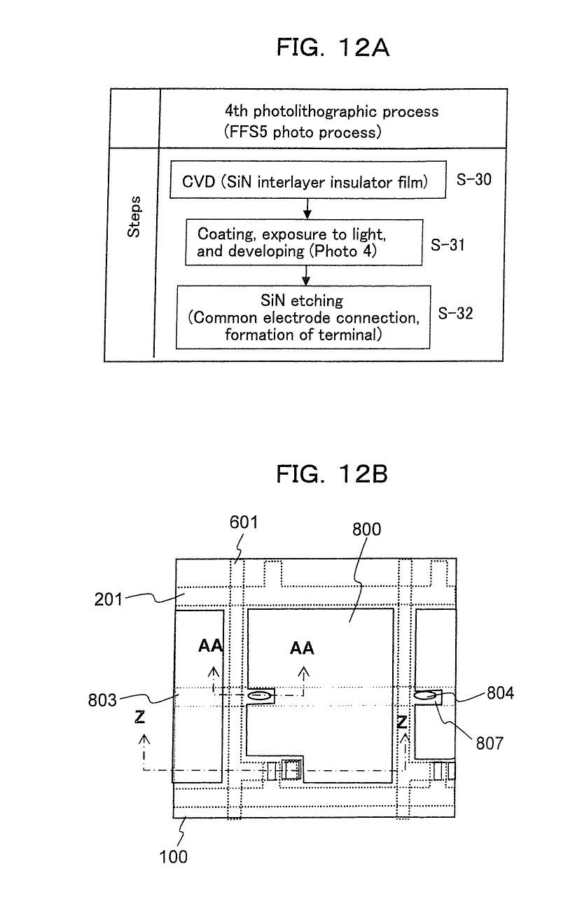

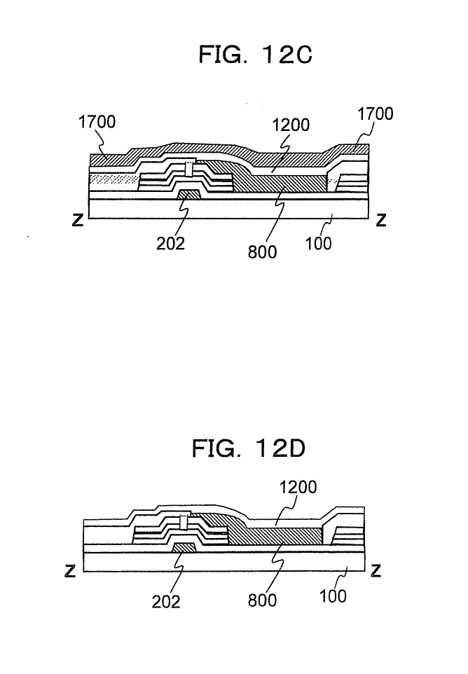

Referring to FIG. 12A to FIG. 15B, description will be given below on the active matrix substrate and a method of manufacturing it in the Embodiment 4 of the invention. The Embodiment 4 is a variation of the Embodiment 3, and an active matrix substrate for the FFS type liquid crystal display device can be manufactured in 5 photolithographic processes, i.e. by merely one more additional processes compared with the case of the Embodiment 3. In the Embodiment 4, the first photolithographic process to prepare the gate line, the gate electrode and the additional capacity line (common line) on the substrate, the second photolithographic process to prepare the thin film transistor channel, and the third process to form the pixel electrode are the same as in the Embodiment 3 described above, and detailed description is not given here. In the following, description will be given only on the fourth photolithographic process of the Embodiment 4.

FIG. 12A is a drawing to explain the steps in the fourth photolithographic process in the Embodiment 4 of the invention. First, on a substrate where a pixel electrode 800 has been prepared in the Embodiment 3, an interlayer insulator film (SiN) is deposited by CVD (Step S-30). On it, a photo resist is coated, and it is exposed to light (Step S-31). Then, it is developed and etching is performed on an interlayer insulator film between the common electrode connection and the terminal, and the common electrode connection and the terminal are exposed (Step S-32).

FIG. 12B is a plan view of an essential portion of the pixel region on the substrate where the pixel electrode is prepared. FIG. 12C is a cross-sectional view along the line Z-Z of FIG. 12B to explain the steps, i.e. to deposit an interlayer insulator film (SiN) on a substrate by CVD where the pixel electrode is prepared. Then, a photo resist 1700 is coated on it and this is exposed to light by using an exposure mask. It is then developed and the resist pattern is prepared. FIG. 12D shows that etching is performed on the interlayer insulator film of the common electrode connection by using the resist pattern as an etching mask, and then, the resist is removed (FIG. 138). In FIG. 12D, it is shown that simply the resist is removed.

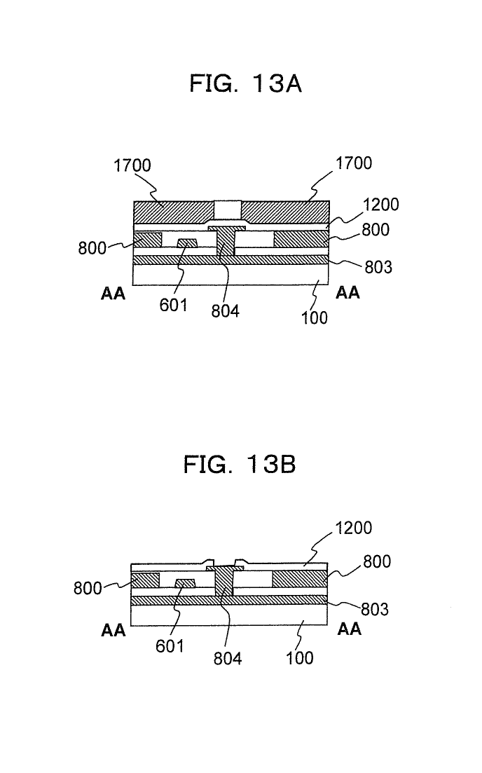

Each of FIG. 13A and FIG. 13B represents a cross-sectional view of the common electrode connection along the line AA-AA in FIG. 12B. FIG. 13A shows the steps that the photo resist 1700 is coated on the interlayer insulator film 1200 deposited on the interlayer insulator film 1200. Then, after patterning, an opening is provided above the portion of the common electrode connecting electrode 804. FIG. 13B shows that the resist pattern of FIG. 13A is used as an etching mask, and etching is performed on the interlayer insulator film 1200, and the common electrode connecting electrode 804 is exposed.

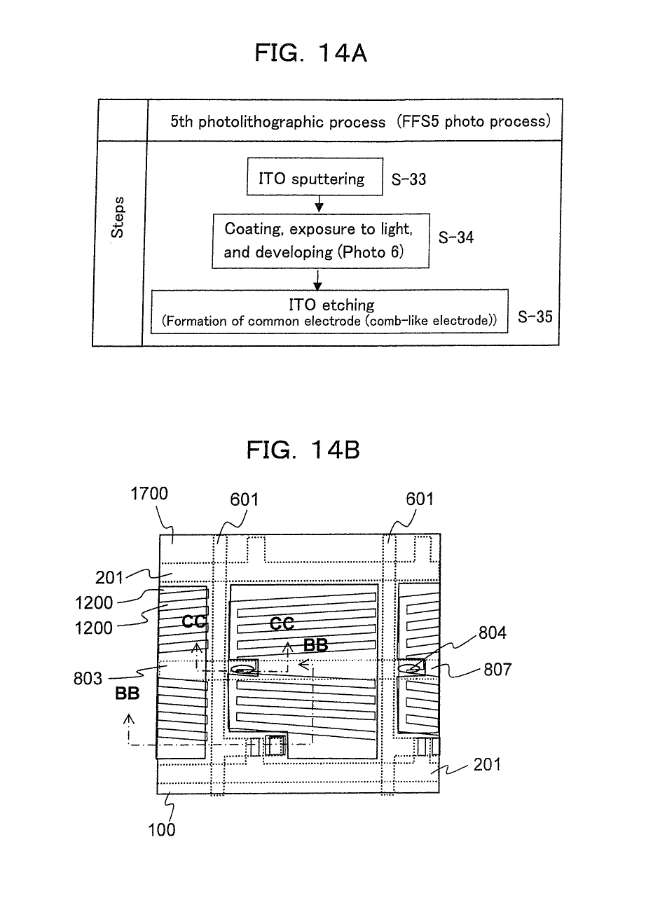

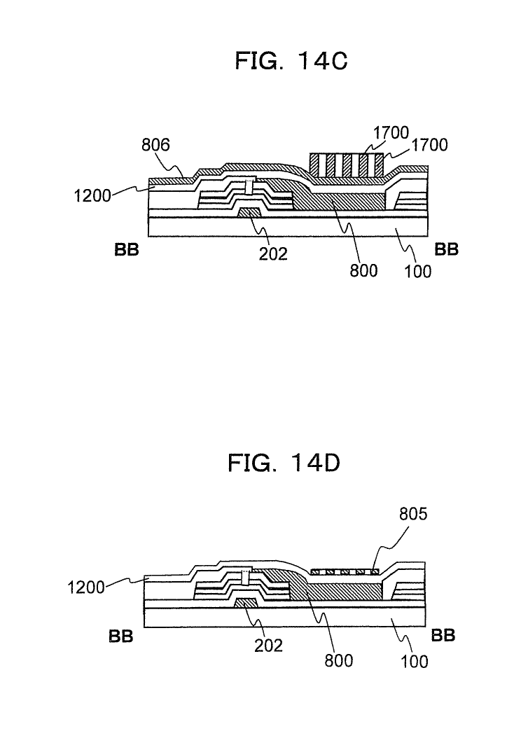

FIG. 14A is a drawing to explain the steps of the process to prepare the common electrode. First, on the substrate as explained in connection with FIG. 12D and FIG. 13B, a transparent conductive material (preferably ITO) is sputtered (Step S-33). Then, the photo resist is coated on it. After exposure is performed by using the exposure mask, it is developed, and a resist pattern for preparing a comb-like common electrode is prepared (Step S-34). Then, etching is performed on ITO by using this resist pattern, and a comb-like common electrode is prepared (Step S-35).

FIG. 14B is a plan view of an essential portion of the pixel region of the Embodiment 4. FIG. 14C is a cross-sectional view along the line BB-BB of FIG. 14B, showing a condition where the pattern of resist 1700 for preparation of the common electrode is formed on ITO. By using this resist pattern as an etching mask, etching is performed on ITO 806, and a comb-like common electrode 805 is formed by performing etching on the ITO 806. This step is shown in FIG. 14D.

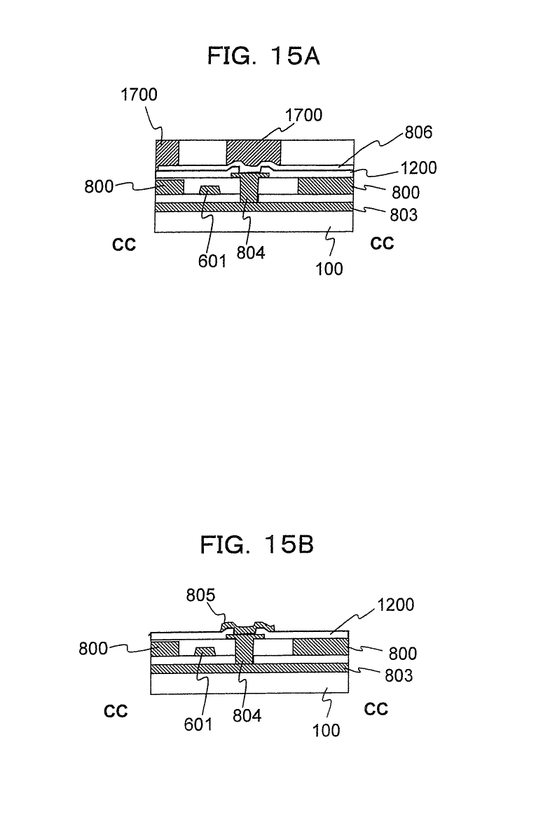

FIG. 15A is a cross-sectional view along the line CC-CC of FIG. 14B. The photo resist 1700 is coated on the ITO 806. Then, it is exposed to light and it is developed and patterning is performed. Using this resist as an etching mask, etching is performed on the ITO 806 and a comb-like common electrode connected to the common electrode connecting electrode 804 is prepared.

In the Embodiment 4 of the invention as described above, it is also possible to manufacture the active matrix substrate and the liquid crystal display device by decreasing the number of the photolithographic processes, and the FFS type liquid crystal display device can be produced at inexpensive cost.

### Embodiment 5

Referring to FIG. 16 to FIG. 21E, description will be given below on the active matrix substrate and a method of manufacturing it according to the Embodiment 5 of the invention. The Embodiment 5 relates to an active matrix substrate for a liquid crystal display device (FFS-COA mode), i.e. the FFS type liquid crystal display device with a color filter disposed on the TFT substrate side. In the Embodiment 5, the first photolithographic process to prepare a gate line, a gate electrode and a common line on the substrate and the second photolithographic process to prepare a channel of the thin film transistor are the same as in the Embodiment 4, and detailed description is not given here. In the following, description is given on the third photolithographic process of the Embodiment 5.

FIG. 16 is a drawing to explain the process of the FFS-COA type liquid crystal display device, i.e. the process where a gate line, a gate electrode, and a common line are prepared, and a channel of thin film transistor is disposed on a TFT substrate where a color filter and a pixel electrode are provided. First, on the TFT substrate where the gate line, the gate electrode and the common line are prepared and the channel of the thin film transistor is disposed, photo resist is coated by a slit coater, and a resist pattern is formed, which fulfills the function of the resist bank for preparing a pixel electrode, a color filter, and a common electrode (Step S-36). Using the resist pattern as an etching mask, a gate insulator film is prepared by etching, and a gate line terminal, a common line terminal, a data line terminal, a contact hole for connecting the data line and the data line terminal, and a contact hole for connecting the common electrode to the common line are prepared (Step S-37).

Ashing is performed on the resist pattern and the resist on the half-tone exposed region is removed (Step S-38). An ink containing a color filter material dispersed in it is coated on the pixel region by inkjet method (Step S-39). Then, an ink containing a transparent conductive film material (preferably ITO) dispersed in it is coated by inkjet method, and a pixel electrode is prepared. Then, an ITO film is embedded in the contact hole for connecting the data line and the data line terminal, and also in the contact hole for connecting the common electrode to the common line to keep contact (Step S-40).

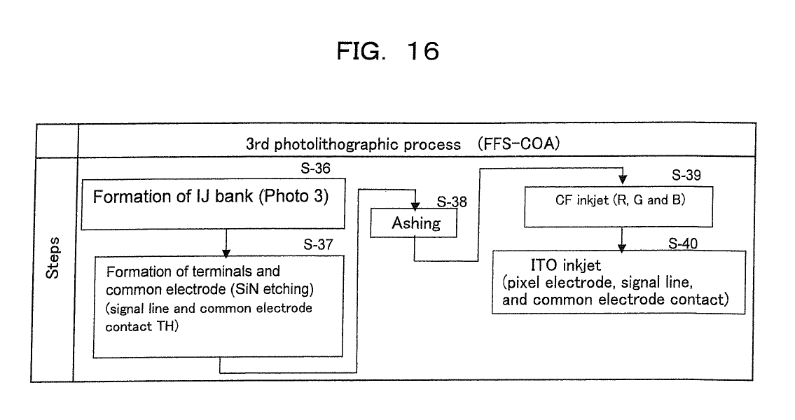

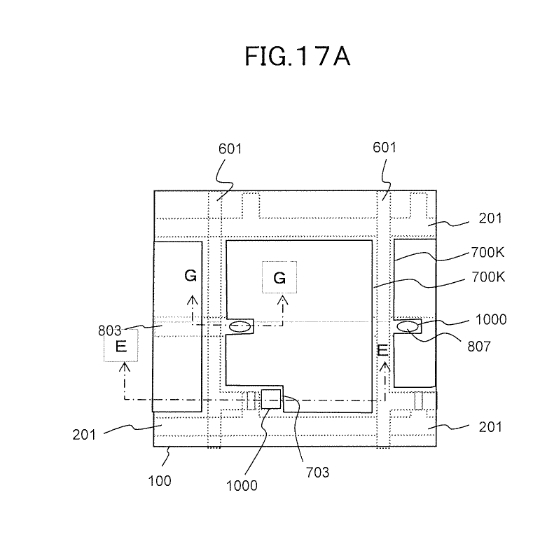

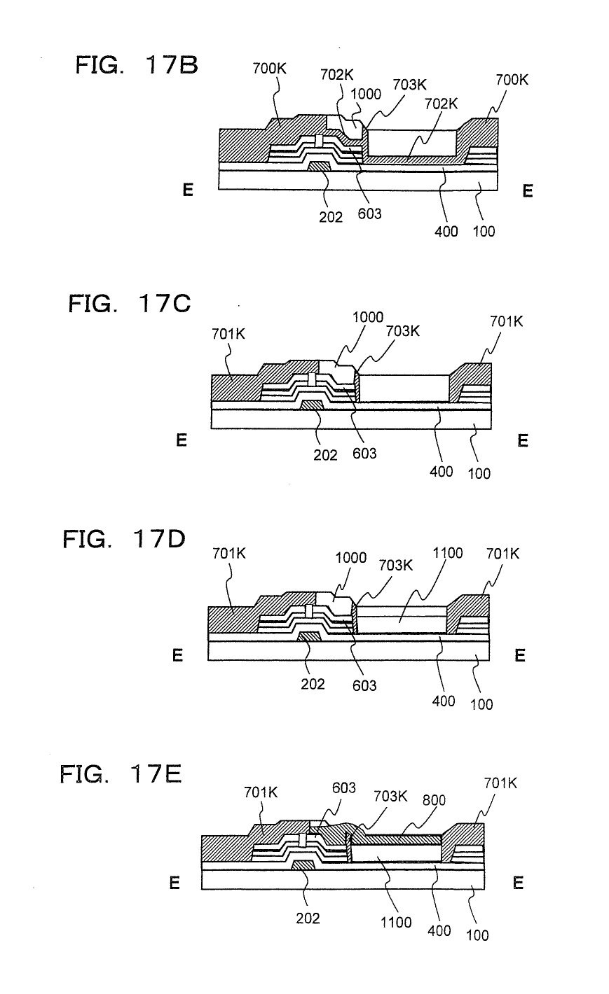

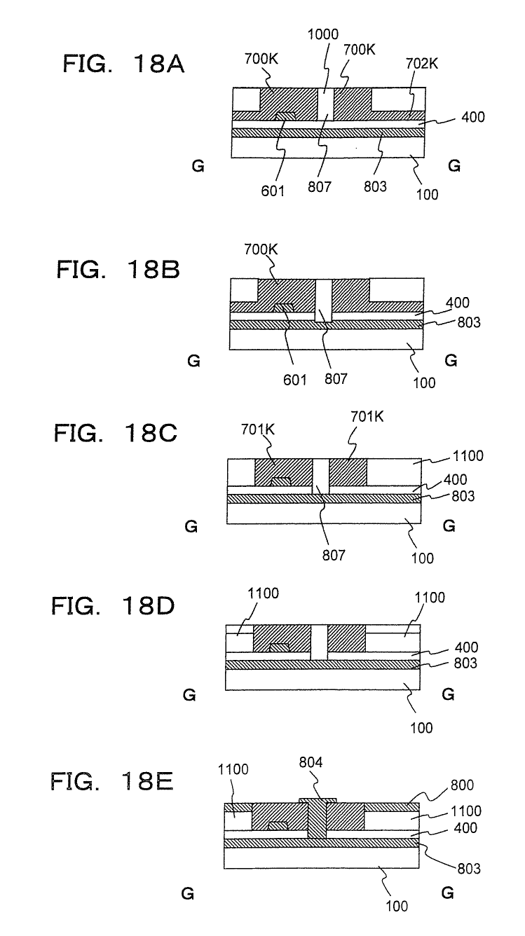

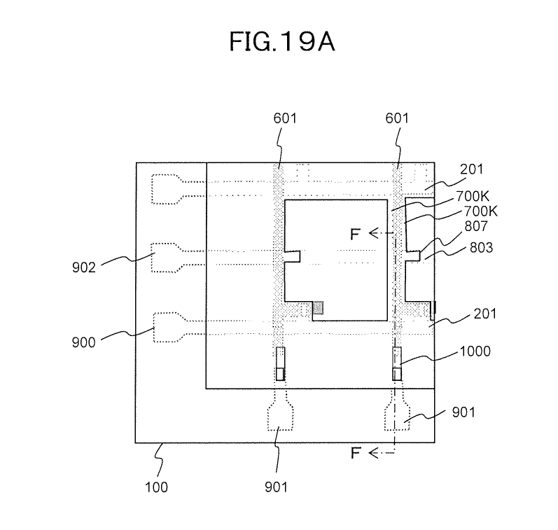

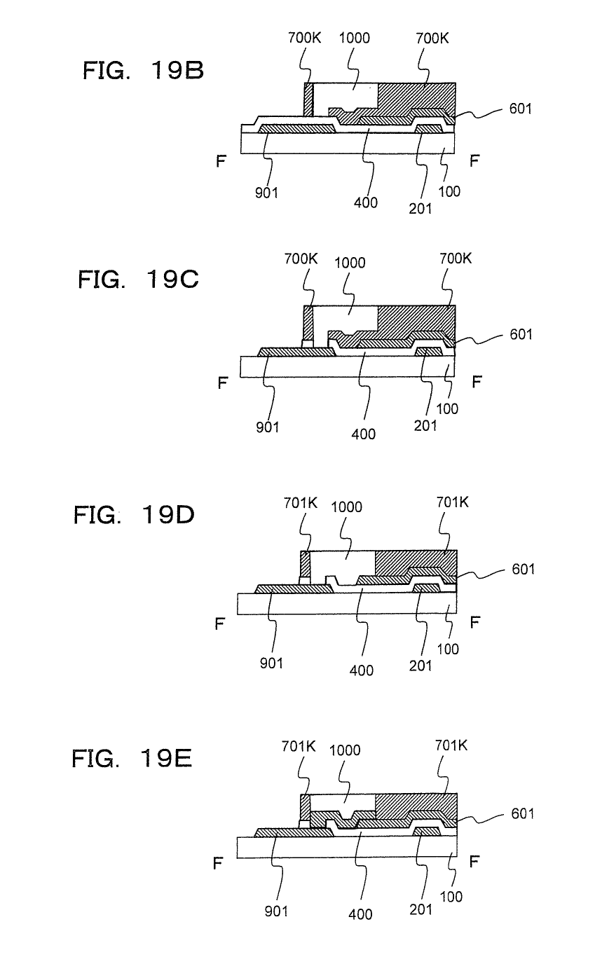

FIG. 17A is a plan view of an essential portion of an image region of the active matrix substrate according to the Embodiment 5 of the invention. In a region surrounded by two gate lines 201 and two data lines 601 on the substrate 100, one unit pixel (each color pixel in case of color display; sub-pixel) is formed. Each of FIG. 17B to FIG. 17E represents a cross-sectional view along the line E-E of FIG. 17A, and each of FIG. 18A to FIG. 18E represents a cross-sectional view along the line G-G in FIG. 17A. FIG. 19A is a plan view of an essential portion of the terminal of the active matrix substrate according to the Embodiment 5 of the invention. Each of FIG. 19B to FIG. 19E represents a cross-sectional view along the line F-F in FIG. 19A.

Referring to FIG. 17A to FIG. 19E, description will be given on a method of manufacturing the active matrix substrate according to the Embodiment 5 of the invention. In FIG. 17A and in FIG. 17B to FIG. 17E, a resist 700K intermingled with a black color material is processed by the half-tone exposure method. Then, it is developed, and a bank 700K is prepared. Thin resist film 702K processed by the half-tone exposure method is prepared on the region of the pixel electrode and the contact hole 100 for connecting the pixel electrode to the drain electrode of the thin film transistor. The common line 803 is disposed on central portion of the pixel in a direction parallel to the gate line 210. On the region where the pixel electrode is formed, a part of the bank is protruded above the common line 803, and a common electrode connection 807 is prepared, and the contact hole 1000 is disposed on the common electrode connection 807.

In FIG. 17B, the resist 700K is exposed to light. On the resist pattern after developing, a ridge 703K is formed between a color filter coated portion of the pixel region and a drain region of the thin film transistor. This ridge 703K fulfills the function as a wall to prevent the overflow of the color filter ink to the drain electrode 603 of the thin film transistor when the color filter 1100 is coated on the resist bank 701K after ashing as shown in FIG. 17C to FIG. 17D. After the color filter 1100 is disposed, an ink containing a transparent conductive material (preferably ITO) dispersed in it is coated in the resist bank 701K by inkjet method, and the pixel electrode 800 is prepared. The ITO ink is also coated on the drain electrode 603 of the thin film transistor beyond the ridge 703K, and the pixel electrode 800 is connected to the drain electrode. This is shown in FIG. 17E.

FIG. 18A to FIG. 18E show the processes for connecting the common electrode and the common line to be explained along the line G-G in FIG. 17A. On the line G-G, a common line 803 is prepared in the pixel region in parallel to the gate line and on the same layer. In FIG. 18A, the common line 803 is covered by the interlayer insulator film 400, and the data line 601 is disposed on it. A photo resist 700K intermingled with a black color material is coated on it, and it is processed by the half-tone exposure using an exposure mask. FIG. 18A shows the resist pattern after developing. The non-exposed region is represented by 700K and the half-tone exposed region is represented by 702K.

Using this resist pattern as an etching mask, etching is performed on the interlayer insulator film 400. The interlayer insulator film 400 of the common electrode connection 807 is removed, and the common line 803 of the lower layer is exposed. This is shown in FIG. 18B. Next, ashing is performed on the resist, and the resist on the half-tone exposed region is removed. The resist 701 is now turned to a resist bank (FIG. 18C). Using the inkjet method, an ink containing a color filter material is coated inside the bank 701K (FIG. 18D). Then, an ITO ink containing a transparent conductive material (preferably ITO) dispersed in it is coated by inkjet method, and the pixel electrode 800 and the common electrode connecting electrode 804 are prepared. The common electrode connecting electrode 804 is filled in the common electrode connection 807 and is connected to the common electrode 803. This is shown in FIG. 18E.

FIG. 19A is a plan view of an essential portion of the terminal of the active matrix substrate according to the Embodiment 5 of the invention. As explained in connection with FIG. 17A, the resist 700K intermingled with a black color material is processed by the half-tone exposure method. Then, it is developed, and a resist bank 700K is prepared. FIG. 19A to FIG. 19E show the processes to connect the data line to the data line terminal 901. FIG. 19B shows that the contact hole 1000 for connecting the data line 601 to the data line terminal 901 has the resist processed by the half-tone exposure.

FIG. 19C shows that etching performed on the interlayer insulator film 400 by using the resist pattern of FIG. 19B as an etching mask, and the interlayer insulator film 400 is removed from the terminal 901 and the contact hole 1000. Then, ashing is performed, and the thickness of the resist pattern is reduced, and the resist on the half-tone exposed region is removed (FIG. 19D). An ITO ink containing a transparent conductive material (preferably ITO) is coated by inkjet method. The transparent conductive material is filled in the contact hole 1000, and the data line 601 is connected to the data line terminal 901 via the terminal connection 801 (FIG. 19E).

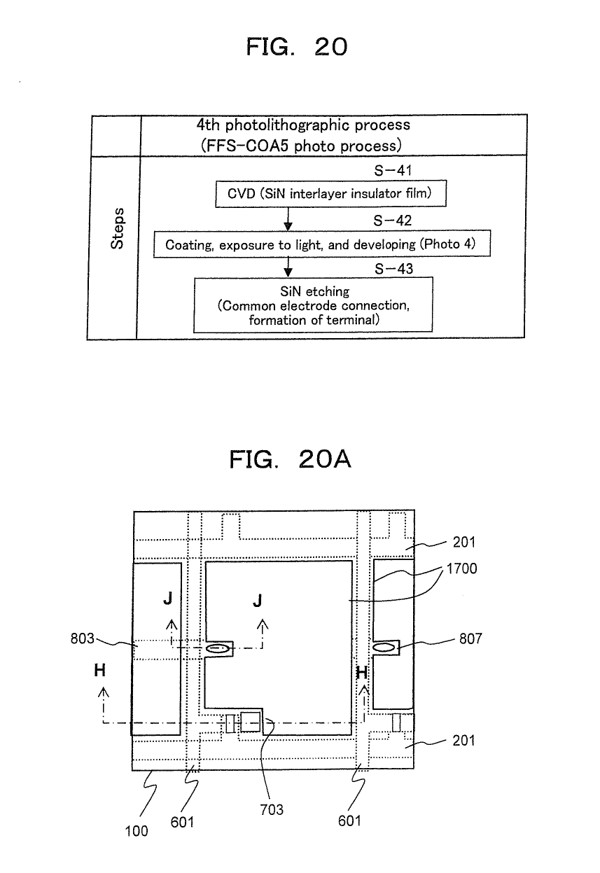

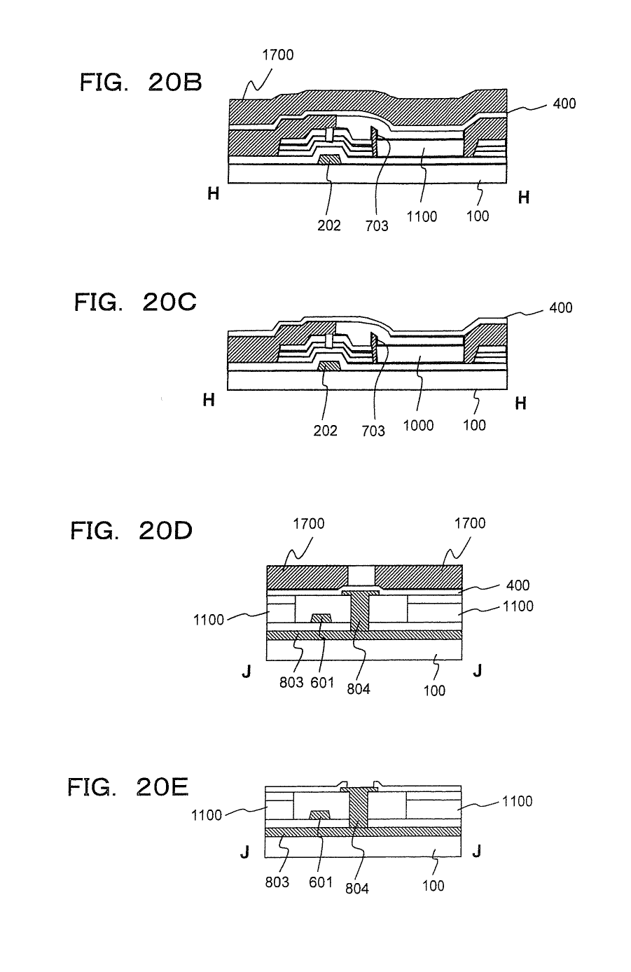

FIG. 20 shows the processes for forming the common electrode connection of the active matrix substrate according to the Embodiment 5 of the invention. As to be explained in connection with FIG. 20A to FIG. 20E, the interlayer insulator film is deposited by CVD on the substrate shown in FIG. 17E in this process. Here, SiN is used as the interlayer insulator film (Step S-41). Resist is coated to cover the interlayer insulator film. After light exposure and developing (Step S-42), etching is performed on the common electrode connection and on the interlayer insulator film of the terminal (Step S-43).

FIG. 20A is a plan view of the pixel region. A cross-sectional view along the line H-H is shown in each of FIG. 20B to FIG. 20C respectively, and a cross-sectional view along the line J-J is given in FIG. 20D to FIG. 20E respectively. In FIG. 20B, the interlayer insulator film 400 is deposited, and the resist 1700 is coated on it. A resist pattern is prepared by the exposure to light. Etching is performed on the interlayer insulator film, and the terminal and others are exposed. On the pixel region, the resist is removed, and the interlayer insulator film 400 is exposed (FIG. 20C).

FIG. 20D shows that a resist opening is formed above the common electrode connecting electrode 804. Through the opening, etching is performed on the interlayer insulator film 400, and the common electrode connecting electrode 804 is exposed (FIG. 20E). On it, the common electrode is disposed by the process as to be described below.

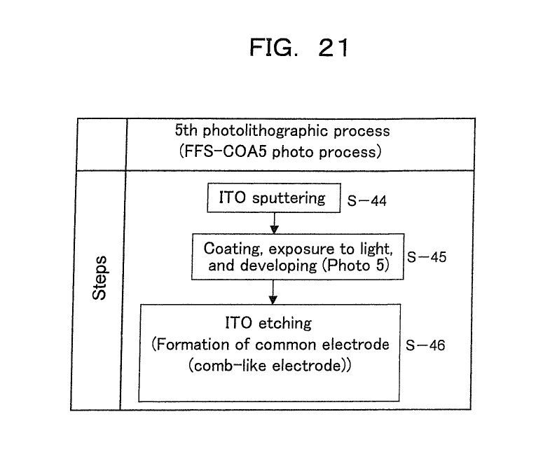

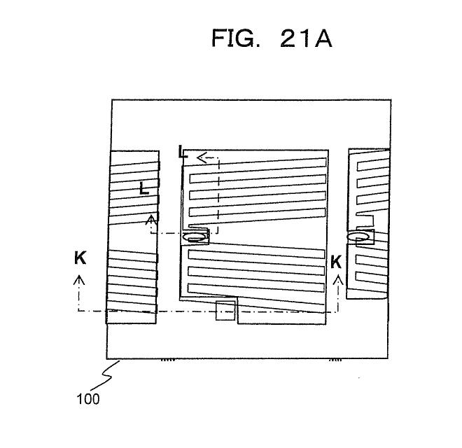

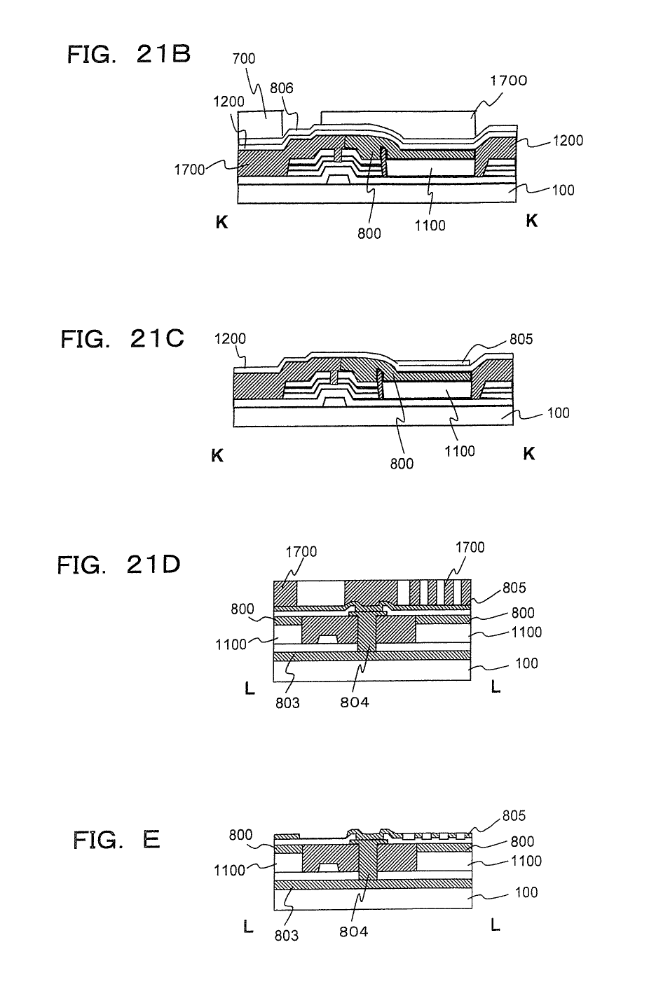

FIG. 21 is a drawing to explain the processes for forming the common electrode of the active matrix substrate according to the Embodiment 5 of the invention. On the interlayer insulator film of the active substrate (TFT substrate) as explained in connection with FIG. 20E, a transparent conductive material (preferably ITO) is deposited by sputtering (Step S-44). On it, the photo resist is coated. After exposure to light and developing, a comb-like resist pattern is formed (Step S-45). Using this resist pattern as an etching mask, a comb-like common electrode is prepared (Step S-46).

FIG. 21A is a plan view of the comb-like common electrode. Each of FIG. 21B and FIG. 21C represents a cross-sectional view to explain the processes to prepare the comb-like common electrode along the line K-K in FIG. 21A. Each of FIG. 21D and FIG. 21E represents a cross-sectional view to explain the process to prepare the comb-like common electrode connection along the line L-L in FIG. 21A. As shown in FIG. 218, ITO is given on the substrate as shown in FIG. 20C by sputtering, and a transparent conductive film (ITO film) 806 is prepared, and a photo resist 1700 is coated on it. Then, light exposure is performed by using an exposure mask having the comb-like common electrode pattern. Then, it is developed, and a resist opening of the comb-like common electrode pattern is formed. FIG. 21C shows the process that etching is performed on the ITO film 806 by using the resist of FIG. 21B as an etching mask, and a comb-like common electrode 805 is prepared.

FIG. 21D shows the processes that ITO is given on the substrate shown in FIG. 20E by sputtering, and a transparent conductive film 806 is prepared. Then, a resist opening is formed between pixels by the exposure of the photo resist of FIG. 21B coated by the photo resist 1700 on it. FIG. 21E shows the process that etching is removed from the ITO film 806 between the adjacent pixels and a comb-like common electrode 805 is prepared. Pixels are separated from each other and the resist 1700 is removed. The comb-like common electrode 805 is connected to the common line 803 via the pixel region connecting electrode 804.

### Embodiment 6

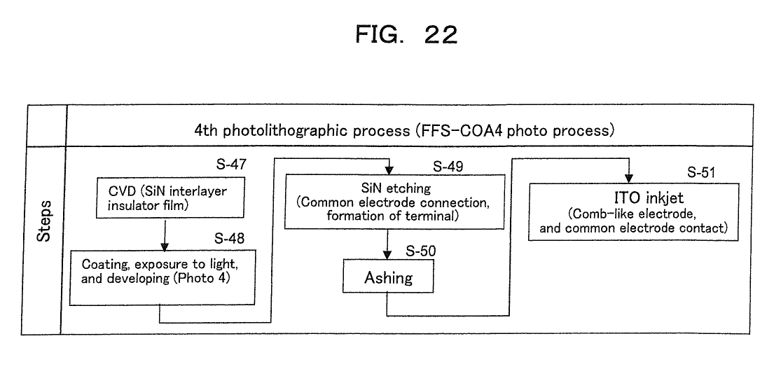

FIG. 22 is a drawing to explain another process for preparing the common electrode on the active matrix substrate according to the Embodiment 6 of the invention. On the TFT substrate as shown in FIG. 17E and FIG. 18E, SiN is deposited by CVD, and an interlayer insulator film is prepared (Step S-47). A photo resist is coated on the interlayer insulator film, and the half-tone exposure is performed by using a half-tone exposure mask (Step S-48). Etching is performed on the interlayer insulator film, and the common electrode connection and the terminal are exposed (Step S-49). Ashing is performed on the photo resist (Step S-50), and the resist on the comb-like common electrode, which is a half-tone exposed region, is opened. On it, ITO is coated by inkjet method, and the comb-like electrode is prepared and the common electrode connecting electrode is connected with the comb-like electrode (Step S-51).

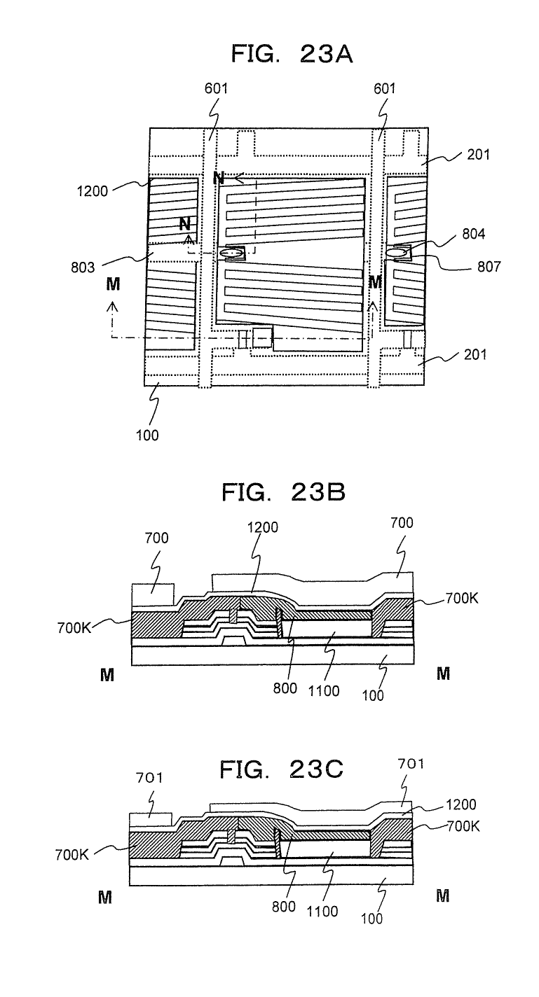

FIG. 23A is a plan view of the pixel region of the active matrix substrate according to the Embodiment 6 of the invention. Comb-like electrode and others are shown virtually. Each of FIG. 23B and FIG. 23C is a cross-sectional view along the line M-M of FIG. 23A. FIG. 23B shows that the interlayer insulator film 1200 is processed by the half-tone exposure and a resist pattern is prepared. FIG. 23C shows the process to perform ashing on the resist pattern.

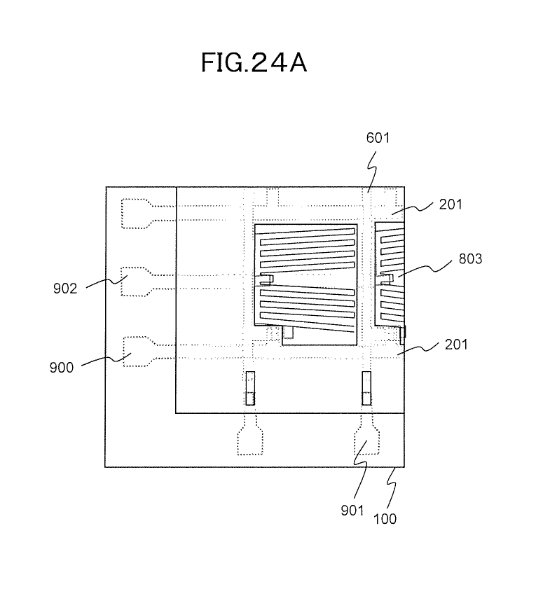

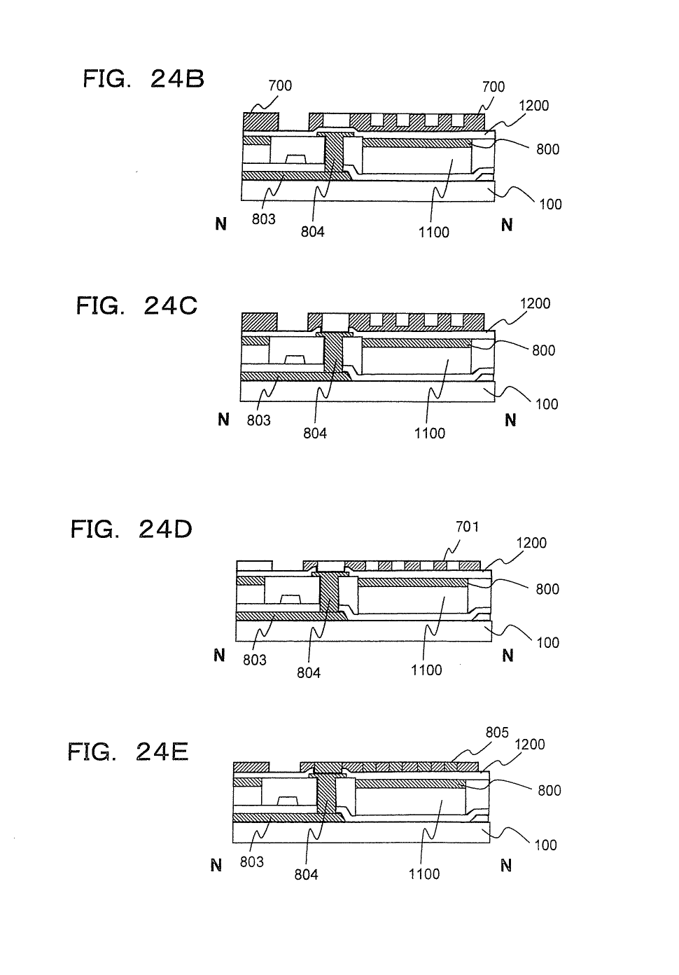

FIG. 24A is a plan view of the terminal of the active matrix substrate according to the Embodiment 6 of the invention. The comb-like electrode and others are shown virtually. Each of FIG. 24B to FIG. 24E is a cross-sectional view along the line N-N in FIG. 23A. FIG. 24B shows a resist pattern prepared by processing the interlayer insulator film 1200 by the half-tone exposure. FIG. 24C shows that etching is removed from the interlayer insulator film 1200 of the common electrode connection, and the common electrode connecting electrode 804 is exposed. FIG. 24D shows that ashing is performed on the resist pattern. FIG. 24E shows that ITO is coated by inkjet method on the opening of the comb-like electrode penetrated by ashing and on the common electrode connecting electrode 804 by inkjet method.

In the Embodiments 5 and 6 of the invention as described above, by reducing the number of the photolithographic processes, it is possible to manufacture the active matrix substrate and the liquid crystal display device by decreasing the number of processes as a whole. Compared with the Embodiment 5 of the invention, it is possible in the Embodiment 6 to reduce the number of the photolithographic processes by one process. In both of the Embodiment 5 and the Embodiment 6, the color filter is disposed on the TFT substrate side, and this makes it possible to improve the numerical aperture without taking the alignment tolerance with the counter substrate into account. As a result, power consumption in the manufacture of the liquid crystal display device can be reduced, and an inexpensive glass substrate or a plastic substrate with higher light transmittance can be adopted as the counter substrate different from the TFT substrate, and the FFS-COA type liquid crystal display device of color filter on array mode with lower material cost can be provided.

### Embodiment 7

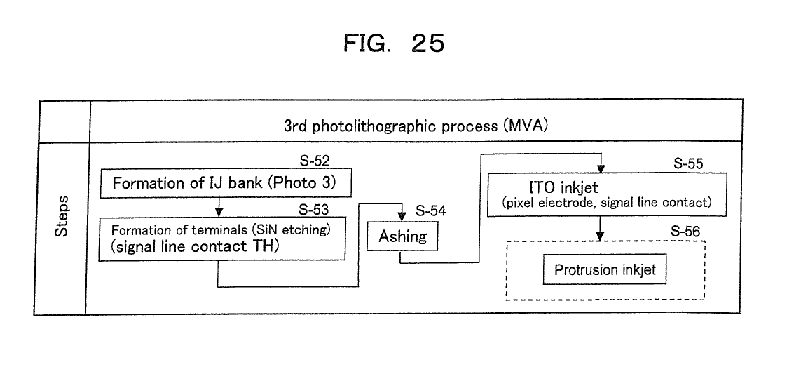

FIG. 25 is a drawing to explain the processes to prepare a TFT substrate of multi-domain vertical alignment (MVA) mode according to the Embodiment 7 of the invention. In this process, on the TFT substrate where two photolithographic processes are performed as in the Embodiment 1, a resist bank is formed on the pixel region by a slit coater (Step S-52). Etching is performed on the region of the interlayer insulator film where there is no resist, and a contact hole for connecting the terminal with signal line is exposed (Step S-53). Next, ashing is performed on the resist (Step S-54), and ITO is coated on the contact hole of the pixel electrode and the signal line by inkjet method (Step S-55).

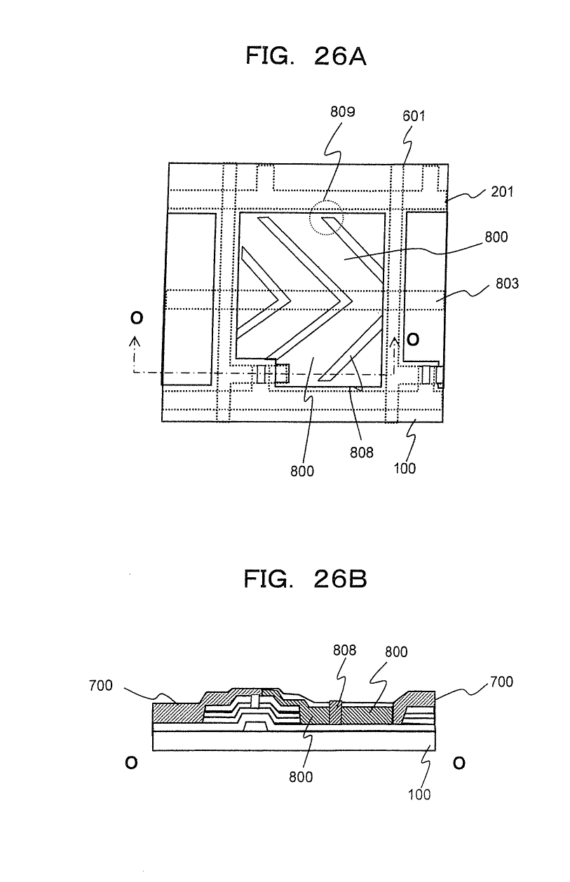

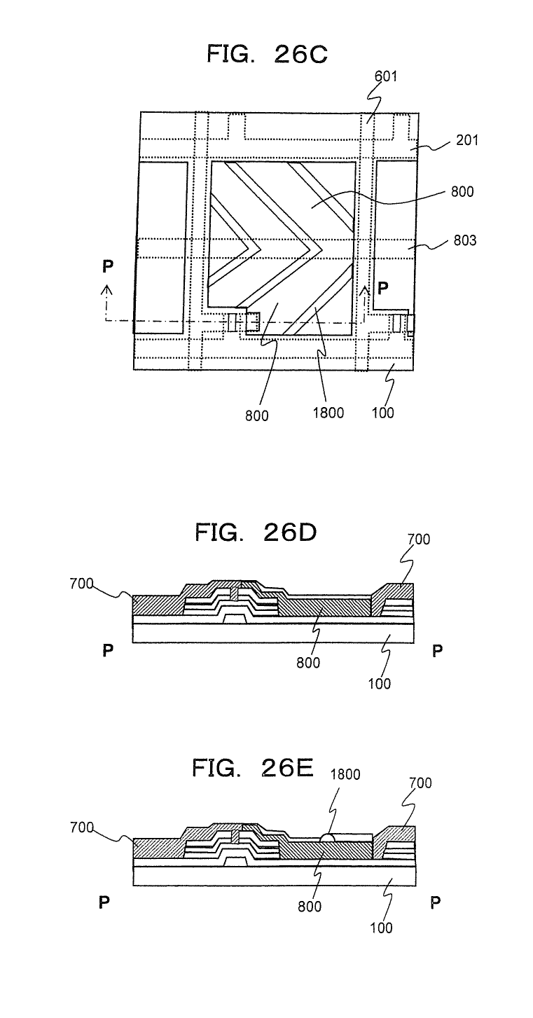

FIG. 26A is a plan view to show one pixel portion of the TFT substrate according to the Embodiment 7 of the invention. FIG. 26B is a cross-sectional view along the line O-O in FIG. 26A. In this Embodiment, the pixel electrode 800 is prepared by coating an ITO ink inside the bank formed by the resist 700. The pixel electrode 800 is divided by a slit-like pixel divider 808 made of resist. On each of upper half and lower half of the pixel (in FIG. 26A, in an extending direction of the data line 601), tilting of each of the divided pixel electrodes is reversed, and direction of the domain is set to two directions, and the divided pixel electrodes are connected via a continuous region 809 provided on upper and lower ends of the pixel.

FIG. 26C is a plan view of a pixel to explain an arrangement of another pixel electrode of multi-domain vertical alignment (MVA) mode according to the Embodiment 7 of the invention. FIG. 26D and FIG. 26E each represents a cross-sectional view along the line P-P of FIG. 26C. The pixel electrode 800 is prepared by coating an ITO ink inside the bank formed by the resist 700 by inkjet method (FIG. 26D). As shown in FIG. 26E, a protrusion 1800 of resist is prepared by coating at an inclination similar to that of the pixel divider 808 of FIG. 26A by inkjet method on the pixel electrode 800 (Step S-56 shown in FIG. 25). By this protrusion 1800, two domains are formed.

In the Embodiment 7 as described above also, by reducing the number of the photolithographic processes, it is possible to manufacture the active matrix substrate and the liquid crystal display device by reducing the number of processes as a whole, and the liquid crystal display device of MVA mode can be offered at lower cost.

### Embodiment 8

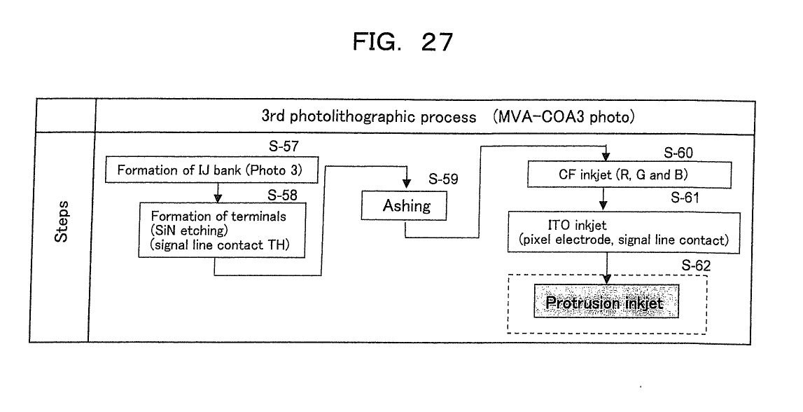

FIG. 27 is a drawing to explain processes to prepare a TFT substrate multi-domain vertical alignment (MVA-COA) mode with a color filter disposed on the TFT substrate side according to the Embodiment 8 of the invention. In this process, a black color resist bank is formed on the pixel region by a slit coater on the TFT substrate prepared by two photolithographic processes similarly to the Embodiment 1 (Step S-57). Etching is performed on a region without resist of the interlayer insulator film, and a contact hole for connecting the terminal and signal line is exposed (Step S-58). Next, ashing is performed on the resist (Step S-59), and a color filter of three colors (R, G and B) is prepared by inkjet method (Step S-60). Further, on this color filter, ITO is coated on the contact hole of the pixel electrode and the signal line by inkjet method (Step S-61).

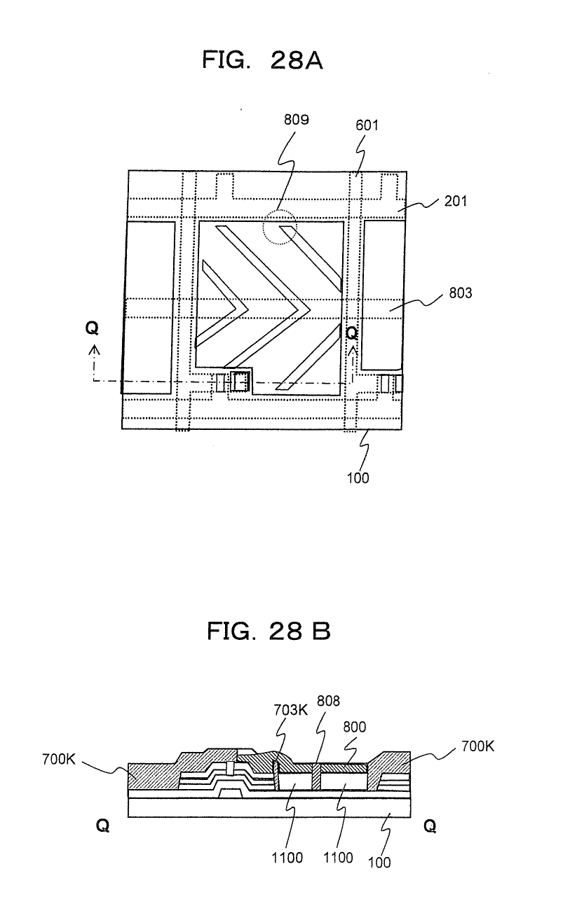

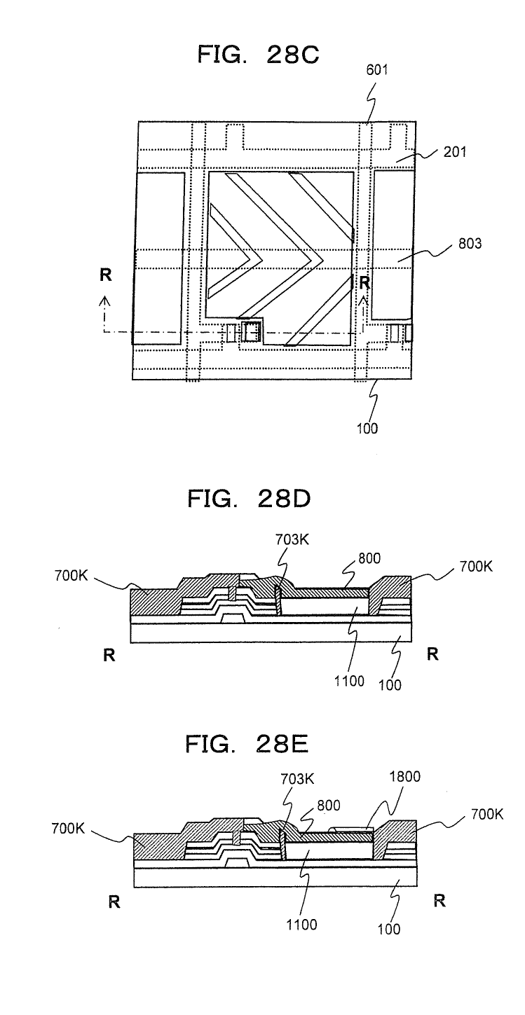

FIG. 28A is a plan view to show one pixel region of the TFT substrate according to the Embodiment 8 of the invention. FIG. 28B is a cross-sectional view along the line Q-Q of FIG. 28A. In this embodiment, the pixel electrode 800 is prepared by coating an ITO ink on the color filter coated inside the bank, which is formed by a black color resist 700K. The pixel electrode 800 is divided by a slit-like pixel divider 808 made of the black color resist, and it is connected to the drain electrode of the thin film transistor beyond the ridge 703 of the black color resist.

FIG. 28C is a plan view of one pixel to explain an arrangement of another pixel electrode of multi-domain vertical alignment (MVA-COA) mode according to the Embodiment 8 of the invention. Each of FIG. 28D and FIG. 28E is a cross-sectional view along the line R-R in FIG. 28C. The pixel electrode 800 is prepared by coating ITO ink by inkjet method on a color filter 1100, which is coated inside the bank formed by the black color resist 700K by inkjet method (FIG. 28D). As shown in FIG. 28E, a resist protrusion 1800 is coated with an inclination similar to that of the pixel divider 808 shown in FIG. 28C by inkjet method (Step S-62 of FIG. 27). By this protrusion 1800, two domains are prepared.

In the Embodiment 8 of the invention also, by reducing the number of the photolithographic processes, it is possible to manufacture the active matrix substrate and the liquid crystal display device by reducing the number of processes as a whole. By disposing the color filter on the TFT substrate side, numerical aperture can be improved without taking the alignment tolerance with the counter substrate into account. As a result, power consumption in the manufacture of the liquid crystal display device can be decreased, and a glass substrate made of a material different from the TFT substrate and available at inexpensive cost or a plastic substrate with higher light transmittance can be adopted as the counter substrate. This contributes to the reduction of the material cost, and the MVA type liquid crystal display device of color filter on array mode can be offered at lower cost.

### Embodiment 9

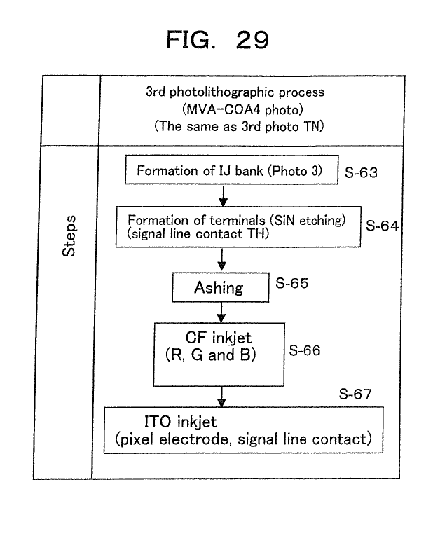

FIG. 29 is a drawing to explain processes for preparing the TFT substrate of multi-domain vertical alignment (MVA-COA) mode with a color filter disposed on the TFT substrate side according to the Embodiment 9 of the invention. The Steps (S-63) to (S-67) of the processes, are the same as the steps (S-16) to (S-20) to prepare the color filter in the Embodiment 2, which is described above in connection with FIG. 6A to FIG. 6E.

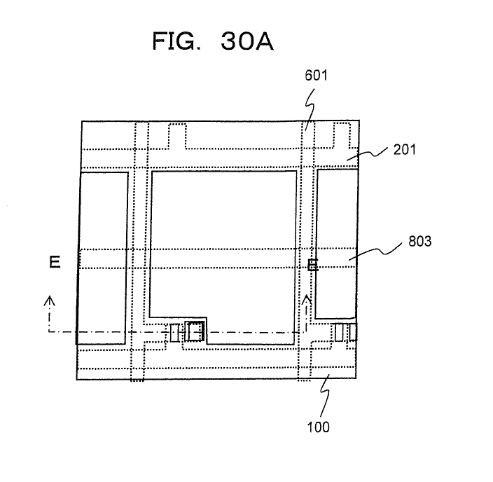

FIG. 30A is a plan view of an essential portion of an image region, showing the process to coat a black color photo resist in the third photolithographic process and it is then processed by the half-tone exposure. The regions processed by the half-tone exposure are a pixel electrode preparing region (color filter is coated on the lower layer of the pixel electrode) and a contact hole region. As shown in FIG. 30B to FIG. 30E, the contact hole 1000 is separated from the pixel electrode preparing region by a ridge 703K.

FIG. 30B shows the processes of the third photolithographic process explained in Step (S-63) of FIG. 29. A black color photo resist 700K is coated on the thin film transistor substrate by a slit coater. Using a half-tone exposure mask, the contact hole connecting the pixel region and the pixel electrode to the drain electrode is processed by the half-tone exposure, and the terminal of the gate line and the terminal of the data line are processed by full-exposure, and a black color bank is formed around the pixel electrode. In this third photolithographic process, the pixel region and the contact hole 1000 are processed by the half-tone exposure, and the resist film is thinner. The black color resist on the thinner half-tone exposed region is represented by 702K. The resist 702K on the half-tone exposed region is enclosed by the black color resist 700K.

FIG. 30C shows that ashing is performed on the black color film 700K and on the black color resist 702K of the half-tone exposed region, and that the thickness is reduced. By ashing, the resists on the pixel region and the contact hole region are removed. The film thickness of the remaining black color resist 701K is thinner by an extent of the black color resist 702K on the removed half-tone exposed region or slightly thinner than that.

FIG. 30D shows that a color filter ink 1100 is coated inside the bank for preparing the pixel to be formed by the black color resist 701K. As shown in FIG. 30E, an ink containing a transparent conductive material (preferably ITO) dispersed in it is dropped to and coated on the color filter 1100 and on a region to the contact hole 1000 beyond the ridge 703K, and the pixel electrode 800 is prepared. The pixel electrode 800 is connected to the drain electrode 603 of the thin film transistor via the contact hole 1000.

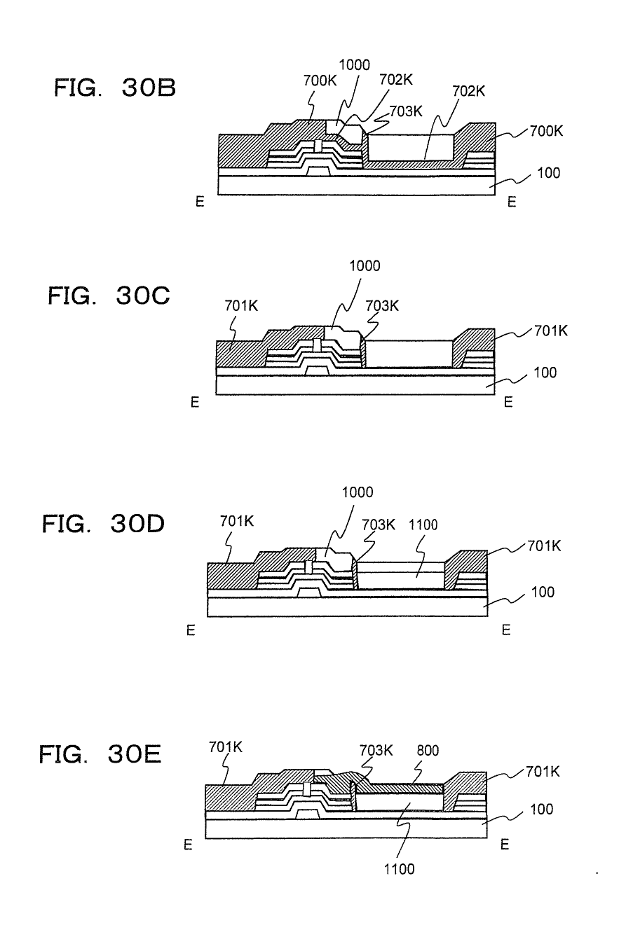

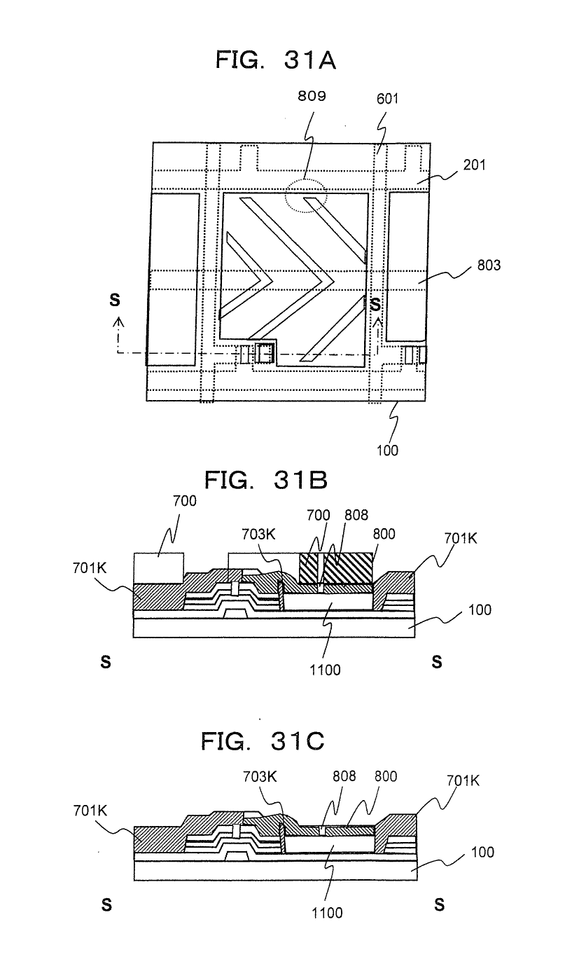

FIG. 31A is a plan view to show one pixel portion of the TFT substrate according to the Embodiment 9 of the invention. FIG. 31B is a cross-sectional view along the line S-S of FIG. 31A. In this Embodiment, the pixel electrode 800 is prepared by coating an ITO inside the bank formed by the black color resist 700K by inkjet method. Then, the resist is coated on the pixel electrode 800, and it is exposed to light by using a mask with the pattern to divide a slit-like pixel divider 808. After developing, etching is performed, and it is divided by the slit-like pixel divider 808. On each of upper half and lower half of the pixel (in extending direction of the data line 601 in FIG. 31A), tilting of each of the pixel electrodes is reversed, and there are two domains. The pixel electrodes thus divided are connected together by a continuous regions provided on an upper end and a lower end of the pixel.

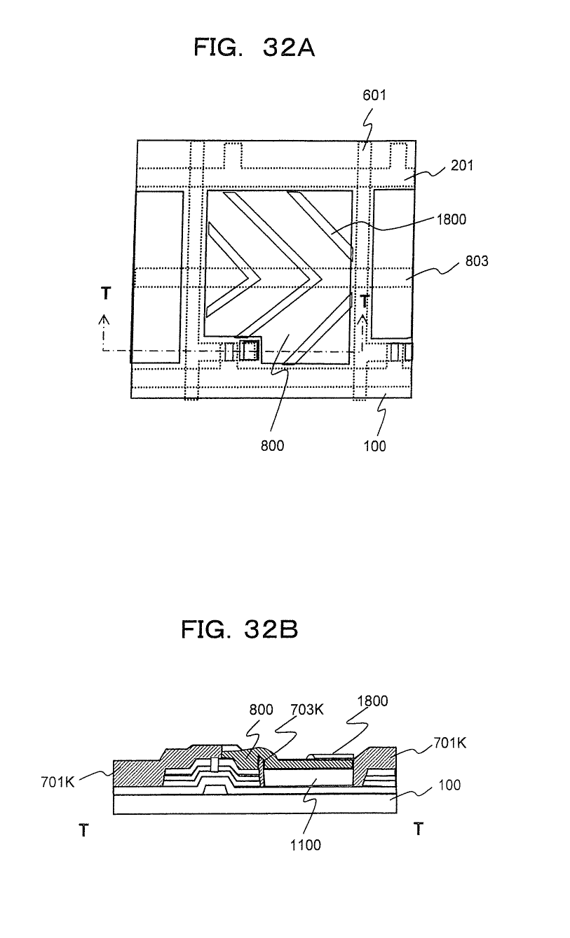

FIG. 32A is a plan view of one pixel to explain an arrangement of another pixel electrode of multi-domain vertical alignment (MVA-COA) mode with a color filter disposed on the TFT substrate side according to the Embodiment 9 of the invention. FIG. 32B is a cross-sectional view along the line T-T of FIG. 32A. The pixel electrode 800 is prepared by coating an ITO ink inside the bank formed by the black color resist 700K (FIG. 32B). On this pixel electrode 800, the resist is coated by a slit coater, and it is exposed to light by using a mask with the same inclination pattern as that of the pixel divider 808 of FIG. 31A. Then, it is developed and a protrusion 1800 of the resist is prepared (Step S-62 of FIG. 27). By this protrusion, two domains are formed.

In the Embodiment 9 of the invention also, by reducing the number of the photolithographic processes, it is possible to manufacture the active matrix substrate and the liquid crystal display device by reducing the number of processes as a whole. By disposing the color filter on the TFT substrate side, numerical aperture can be improved without taking the alignment tolerance with the counter substrate into account. As a result, power consumption in the manufacture of the liquid crystal display device can be decreased, and a glass substrate made of a material different from the TFT substrate and available at inexpensive cost or a plastic substrate with higher light transmittance can be adopted as the counter substrate. This contributes to the reduction of the material cost, and the MVA type liquid crystal display device of color filter on array mode can be offered at lower cost.

### Embodiment 10

FIG. 33A is a drawing to explain the new process according to the Embodiment 10 of the invention, i.e. the process to prepare the pixel electrode of color filter on array mode, and the half-tone exposure is performed on the resist 700K, which is intermingled with a black color material and is coated by a slit coater. Then, it is developed, and a bank 700K is formed. Each of FIG. 33B and FIG. 33C is a cross-sectional view along the line DD-DD of FIG. 33A. As described above, description is given above in FIG. 6A to FIG. 6F for TN type, in FIG. 16 and FIG. 17A to FIG. 17E for FFS type, in FIG. 27 and from FIG. 28A to FIG. 28B and from FIG. 28C to FIG. 28E for MVA type, description is given above on a single layer of black color resist. By mixing a black color material into the resist, insulating property of the resist may be lost. In this case, IJ bank to be formed by the black color resist is made of two types of materials, and as shown in FIG. 31B, a resist 704 with insulating property is used for the resist of the first layer, and a black color resist 700K is used for the second layer. In so doing, the back channel region of the transistor is embedded with the resist 704 with insulating property, and no current leakage occurs between the source electrode and the drain electrode.

Here, if exposure sensitivity of the resist 704 of the first layer is made lower than the exposure sensitivity of the second layer resist 700K, the remaining film thickness of the resist on the half-tone exposed region 702 can be made more stable with respect to the change of exposure quantity by the half-tone exposure.

FIG. 33D is a cross-sectional view along the line DD-DD of FIG. 33A of one pixel to explain an arrangement of another pixel electrode relating to a process to prepare the bank 700K by processing the resist 700K, which is prepared by mixing a black color material coated by a slit coater is processed by the half-tone exposure and a bank 700K is formed after developing in the process for preparing the pixel electrode of color filter on array mode according to the Embodiment 10 of the invention. Each of FIG. 33E and FIG. 33F is a cross-sectional view to show the process subsequent to the process of FIG. 33D along the DD-DD of FIG. 33A.

In the other embodiments as given above, as shown in FIG. 33D in the cross-sectional view along the line DD-DD before the bank 700K of FIG. 33A is prepared, the insulator film 705 is coated on channel region prepared by the source electrode 602 and the drain electrode 603. Then, as shown in FIG. 33E, the resist 700K mixed with a black color material coated by slit coater is processed by the half-tone exposure, and the bank 700K is formed after developing. Thus, even when the insulating property of the black color resist may be lost, current leakage between the channels can be prevented by the insulator film 705.

FIG. 33F is a cross-sectional view to show the condition after ashing of the black color resist 700K. A condition is shown where the half-tone exposed region of the resist 702 is removed by ashing, and channels are separated by the insulator film 705.

According to the Embodiment 10 of the invention as described above, in the TFT substrate of liquid crystal display device of color filter on array mode, stable operation of the transistor can be ensured and the stability of the process can be improved because the thickness of the resist remaining on the half-tone exposed region can be equalized with respect to the change of exposure light quantity in the half-tone exposure.

### Embodiment 11

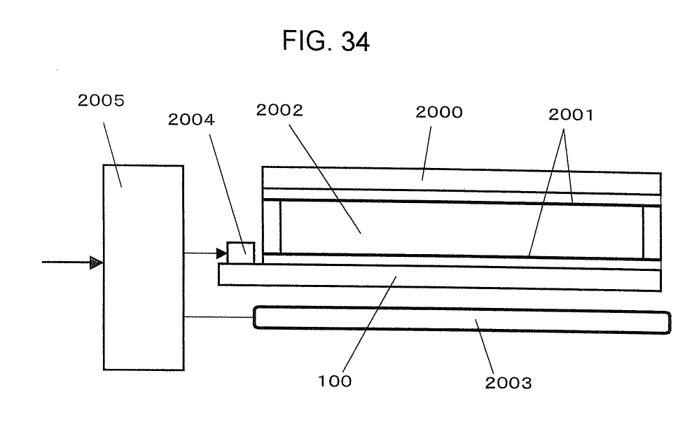

FIG. 34 is a drawing to show an arrangement of a liquid crystal display device to explain an embodiment of the display device according to the invention. This liquid crystal display device is prepared by sealing a liquid crystal 2002 into a gap between an active matrix substrate 100 and a counter substrate 2000 attached together as explained in the embodiment as given above. The same glass material as that of the active matrix substrate 100 or an insulator substrate of inorganic material or an insulating film made of plastics may be used as the counter substrate 2000. On the boundary surface between each substrate and the liquid crystal, an orientation film (alignment layer) 2001 is coated. On rear surface of the active matrix substrate 100, a back light 2003 is provided.

Around the active matrix substrate 100, a driver circuit 2004 is arranged as a circuit directly formed on IC chip or on substrate surface. To the driver circuit 2004, timing signal and image data for display are supplied from the display control device 2005.

### INDUSTRIAL APPLICABILITY

The present invention can be applied—not only to the active substrate, which constitutes a liquid crystal display device, but also to an active substrate for a flat panel display such as an organic electro-luminescent display device. Also, the invention can be applied to various types of semiconductor devices using photolithographic processes.

### LEGENT OF SYMBOLS

100 Insulator substrate
200 Gate metal (metal film for gate line, gate electrode and for capacity line)
201 Gate line
202 Gate electrode
203 Storage capacity line (common line)
300 Resist (photosensitive photo resist)
301 Resist (after ashing)
302 Resist (half-tone exposed region)
400 Gate insulator film (SiN)
500 Semiconductor layer (Si)
501 Ohmic contact layer (n⁺ Si)
600 Source/drain metal (S/D metal: metal film for data line, source electrode, drain electrode)
601 Data line (signal line DL)
602 Source electrode (SD1)
603 Drain electrode (SD2)
604 Channel
700 IJ resist bank (coated by slit coater; half-tone exposure)
701 IJ resist bank (after ashing; bank for preparation of pixel electrode)
702 Resist (half-tone exposed region)
703 Ridge (bank to prevent overflow and leaking of color filter)
704 Insulating resist
705 Insulator film (insulator film for preventing current leakage between channels of source and drain electrodes)
700K IJ black color resist bank
701K IJ black color resist bank (after ashing)
800 Pixel electrode (PX)
801 Terminal connection
803 Common line
804 Common electrode connecting electrode
805 Common electrode
806 ITO (transparent conductive film)
807 Common electrode connection
808 Pixel divider
809 Continuous region
900 Gate line terminal
901 Data line terminal
902 Common line terminal
1000 Contact hole
1100 Color filter
1100G Color filter G (green filter)
1100B Color filter B (blue filter)
1100R Color filter R (red filter)
1200 Interlayer insulator film
1700 Resist
1800 Ridge
2000 Counter substrate
2001 Orientation film (alignment layer)
2002 Liquid crystal
2003 Backlight
2004 Driver
2005 Display control device

1. An active matrix substrate, comprising:
a gate line, a storage capacity line and a data line terminal formed on an insulator substrate;
a gate insulator film to cover said gate line and said storage capacity line;
a plurality of active layer islands formed in array arrangement on said gate insulator film and having an ohmic contact layer separated to a source electrode side and a drain electrode side via a gap to form a semiconductor layer and a channel on an upper layer of the semiconductor;
a source electrode connected to an ohmic contact layer on said source electrode side, and a data line connected to said source electrode; and
one of display electrodes formed by a drain electrode connected to ohmic contact layer on the drain electrode side and by a transparent conductive film continuously connected to the drain electrode, wherein:
said gate insulator film is covered by said one of display electrodes in a region for preparing said one of display electrodes;
a bank of resist is provided to enclose a region where said one of the display electrodes is prepared and to enclose said drain electrode, covering a gap of said ohmic contact layer and said source electrode and said data line, and a data line of adjacent pixel; and
a height from an upper surface of said insulator substrate of said transparent conductive film continuously connected to said one of display electrodes and said drain electrode is lower than a height of said resist bank from an upper surface of said insulator substrate.

2. An active matrix substrate, comprising:
a gate line, a storage capacity line and a data line terminal formed on an insulator substrate;
a gate insulator film to cover said gate line and said storage capacity line;
a plurality of active layer islands formed in array arrangement on said gate insulator film and having an ohmic contact layer separated to a source electrode side and a drain electrode side via a gap to form a semiconductor layer and a channel on an upper layer of the semiconductor;
a source electrode connected to an ohmic contact layer on said source electrode side,
and a data line connected to said source electrode; and
one of display electrodes formed by a drain electrode connected to ohmic contact layer on the drain electrode side and by a transparent conductive film continuously connected to the drain electrode; and
a color filter provided between said one of display electrodes and said gate insulator film, wherein:
a bank of resist is provided to enclose a region where said one of the display electrodes is prepared and to enclose said drain electrode, covering a gap of said ohmic contact layer and said source electrode and said data line, and a data line of adjacent pixel; and
a height of said transparent conductive film from said insulator substrate continuously connected to said one of display electrodes and said drain electrode provided on said color filter is lower than a height of said resist bank from said insulator substrate.

3. An active matrix substrate according to claim 1 wherein:
the other of display electrodes is provided on said one of display electrode via an interlayer insulator film.

4. An active matrix substrate according to claim 1, wherein:
said one of display electrodes is an allover electrode.

5. An active matrix substrate according to claim 3, wherein:
said one of display electrodes is an allover electrode, and said the other of display electrodes is a comb-like electrode.

6. An active matrix substrate according to claim 5, wherein:
said the other of display electrodes is designed in comb-like type and is divided into a plurality of parts within a region of one pixel, and tilting direction of said comb-like electrode is different in each of the divided regions.

7. An active matrix substrate according to claim 1, wherein:
said one of display electrodes is an allover electrode, and a ridge of photo resist to form multi-domain is provided on said allover electrode.

8. An active matrix substrate according to claim 1, wherein:
said one of display electrodes is provided with a slit-like notch with an inclination to be axially symmetric at central portion of the pixel, and multi-domain is formed on said electrode.

9. An active matrix substrate according to claim 2, wherein:
a bank to form said one of display electrodes is designed in laminated structure, and at least the channels are separated by a material with insulating property.

10. An active matrix substrate according to claim 9, wherein:
said bank is designed in laminated layers of a resist with insulating property and a black color resist, and said black color resist is on an upper layer of said resist with insulting property.

11. A method of manufacturing an active matrix substrate, said active matrix substrate comprising:
a gate line, a storage capacity line and a data line terminal formed on an insulator substrate;
a gate insulator film to cover said gate line and said storage capacity line;
a plurality of active layer islands formed in array arrangement on said gate insulator film and having an ohmic contact layer separated to a source electrode side and a drain electrode side via a gap to form a semiconductor layer and a channel on an upper layer of the semiconductor;
a source electrode connected to an ohmic contact layer on said source electrode side, and a data line connected to said source electrode; and
one of display electrodes formed by a drain electrode connected to ohmic contact layer on the drain electrode side and by a transparent conductive film continuously connected to the drain electrode, wherein:
said method comprises the steps of:
coating a photo resist on said data line, said source electrode, and said drain electrode prepared on said insulator substrate;
processing a terminal region of said gate line, a terminal region of said storage capacity line, a terminal region of said data line, and a part of a contact hole for connecting said data line with said terminal region by full-exposure, and a region where one of display electrodes is prepared and said drain electrode are processed by half-tone exposure;
developing said photo resist, removing the photo resist on said full-exposure region, and leaving the photo resist in thinner thickness on said half-tone exposed region;
performing etching and removing said gate insulator film on a region where said photo resist is removed;
performing ashing on said photo resist and removing the photo resist on said half-tone exposed region; and
dropping and coating an ink containing a transparent conductive material to said a region where said one of display electrodes is to be formed by removing photo resist of said half-tone exposed region and to said drain electrode by inkjet method using said photo resist left untouched by said ashing as a bank, and forming said one of display electrodes connected to said drain electrode.

12. A method of manufacturing an active matrix substrate, said active matrix substrate comprises:
a gate line, a storage capacity line and a data line terminal formed on an insulator substrate;
a gate insulator film to cover said gate line and said storage capacity line;
a plurality of active layer islands formed in array arrangement on said gate insulator film and having an ohmic contact layer separated to a source electrode side and a drain electrode side via a gap to form a semiconductor layer and a channel on an upper layer of the semiconductor;
a source electrode connected to an ohmic contact layer on said source electrode side, and a data line connected to said source electrode; and
one of display electrodes formed by a drain electrode connected to ohmic contact layer on the drain electrode side and by a transparent conductive film continuously connected to the drain electrode, wherein:
said method comprises the steps of:
forming said gate line, said storage capacity line and a terminal of said data line on said insulator substrate;
forming a laminated film by continuously depositing said gate insulator film, said semiconductor layer, and said ohmic contact layer in this order to cover said gate line, said storage capacity line, and the terminal of said data line;
fabricating said laminated film on a plurality of active layer islands to make up a thin film transistor, and forming said active layer islands on said insulator substrate in array; and
forming said data line, said source electrode, and said drain electrode on said active layer islands.

13. A method of manufacturing an active matrix substrate according to claim 11, wherein said active matrix substrate comprises:
a gate line, a storage capacity line and a data line terminal formed on an insulator substrate;
a gate insulator film to cover said gate line and said storage capacity line;
a plurality of active layer islands formed in array arrangement on said gate insulator film and having an ohmic contact layer separated to a source electrode side and a drain electrode side via a gap to form a semiconductor layer and a channel on an upper layer of the semiconductor;
a source electrode connected to an ohmic contact layer on said source electrode side, and a data line connected to said source electrode; and
one of display electrodes formed by a drain electrode connected to ohmic contact layer on the drain electrode side and by a transparent conductive film continuously connected to the drain electrode, wherein:
said method comprises the steps of:
forming said gate line, said storage capacity line and a terminal of said data line on said insulator substrate;
forming a laminated film by continuously depositing said gate insulator film, said semiconductor layer, and said ohmic contact layer in this order to cover said gate line, said storage capacity line, and the terminal of said data line;
forming a metal film to be a source line, a source electrode, and a drain electrode to cover total surface of said laminated film;
coating a photo resist on said metal film, performing full exposure by using a half-tone exposure mask with the source electrode and the drain electrode in continuous arrangement and continuous with the source line, and performing half-tone exposure on a channel forming region;
forming a drain electrode continuous to said source line and said source electrode;
fabricating said laminated film on a plurality of active layer islands to make up a thin film transistor by using said pattern as an etching mask, and forming said active layer islands on said insulator substrate in array arrangement;
removing the resist on the half-tone exposed region by aching;
removing a channel region continuous to said source electrode and said drain electrode;
further, forming a back channel by etching of said ohmic contact layer exposed by the etching; and
preparing said data line, said source electrode and said drain electrode on said active layer islands.

14. A method of manufacturing an active matrix substrate, said active matrix substrate comprising:
a gate line, a storage capacity line, and a data line terminal prepared on an insulator substrate;
a gate insulator film to cover said gate line and said storage capacity line;
a plurality of active layer islands formed in array arrangement on said gate insulator film and having an ohmic contact layer separated to a source electrode side and a drain electrode side via a gap to form a semiconductor layer and a channel on an upper layer of the semiconductor;
a source electrode connected to an ohmic contact layer on said source electrode side, and a data line connected to said source electrode; and
one of display electrodes formed by a drain electrode connected to ohmic contact layer on the drain electrode side and by a transparent conductive film continuously connected to the drain electrode, wherein:
said method comprises the steps of:
coating a photo resist on said data line, said source electrode and said drain electrode prepared on said insulator substrate;
performing full exposure on a terminal of said gate line, a terminal of said storage capacity line, and a terminal of said data line, and a part of a contact hole for connecting said data line and said terminal by using a half-tone exposure mask, and performing half-tone exposure on a region where said one of display electrodes is prepared and on said drain electrode;
developing said photo resist, removing the photo resist on said fully exposed region, and leaving a thinner photo resist of said half-tone exposed region;
removing said gate insulator film on a region where said photo resist is removed by etching;
performing ashing on said photo resist and removing the photo resist on said half-tone exposed region; and
after forming a color filter by coating an ink containing a color filter material by inkjet method on a region to prepare said one of display electrodes where the photo resist in said half-tone exposed region is removed by using said photo resist remaining after said ashing as a bank; and
coating an ink containing a transparent conductive material on said color filter and on said drain electrode by inkjet method using said photo resist remaining after said ashing as a bank, and forming said one of display electrodes where said drain electrode is connected.

15. A method of manufacturing an active matrix substrate according to claim 14, wherein said active matrix substrate comprises:
a gate line, a storage capacity line and a data line terminal formed on an insulator substrate;
a gate insulator film to cover said gate line and said storage capacity line;
a plurality of active layer islands formed in array arrangement on said gate insulator film and having an ohmic contact layer separated to a source electrode side and a drain electrode side via a gap to form a semiconductor layer and a channel on an upper layer of the semiconductor;
a source electrode connected to an ohmic contact layer on said source electrode side, and a data line connected to said source electrode; and
one of display electrodes formed by a drain electrode connected to ohmic contact layer on the drain electrode side and by a transparent conductive film continuously connected to the drain electrode, wherein:
said method comprises the steps of:
forming said gate line, said storage capacity line and a terminal of said data line on said insulator substrate;
forming a laminated film by continuously depositing said gate insulator film, said semiconductor layer, and said ohmic contact layer in this order to cover said gate line, said storage capacity line, and the terminal of said data line;
fabricating said laminated film on a plurality of active layer islands to make up a thin film transistor, and forming said active layer islands on said insulator substrate in array; and
forming said data line, said source electrode and said drain electrode on said active layer islands.

16. A method of manufacturing an active matrix substrate according to claim 14, wherein said active matrix substrate comprises:
a gate line, a storage capacity line and a data line terminal formed on an insulator substrate;
a gate insulator film to cover said gate line and said storage capacity line;
a plurality of active layer islands formed in array arrangement on said gate insulator film and having an ohmic contact layer separated to a source electrode side and a drain electrode side via a gap to form a semiconductor layer and a channel on an upper layer of the semiconductor;
a source electrode connected to an ohmic contact layer on said source electrode side, and a data line connected to said source electrode; and
one of display electrodes formed by a drain electrode connected to ohmic contact layer on the drain electrode side and by a transparent conductive film continuously connected to the drain electrode, wherein:
said method comprises the steps of:
forming said gate line, said storage capacity line and a terminal of said data line on said insulator substrate;
forming a laminated film by continuously depositing said gate insulator film, said semiconductor layer, and said ohmic contact layer in this order to cover said gate line, said storage capacity line, and the terminal of said data line;
forming a metal film to be a source line, a source electrode, and a drain electrode to cover total surface of said laminated film;
coating a photo resist on said metal film, and by using a half-tone mask, performing full exposure on the source electrode and the domain electrode continuous to each other (a channel region is not formed) and continuous with the source line, and performing half-tone exposure on a channel forming region forming a drain electrode continuous to the source line and the source electrode by using this pattern as an etching mask;
fabricating said laminated film on a plurality of active layer islands to make up a thin film transistor, and forming said active layer islands on said insulator substrate in array arrangement;
removing the resist on the half-tone exposed region by ashing, removing a channel region continuous to said source electrode and said drain electrode, and further, forming a back channel by etching of said ohmic contact layer exposed by the etching; and
preparing said data line, said source electrode and said drain electrode on said active layer islands.

17. A method of manufacturing an active matrix substrate according to claim 11, wherein:
the other of display electrodes is formed on said one of display electrodes via an interlayer insulator film.

18. A method of manufacturing an active matrix substrate according to claim 11, wherein:
a region where full exposure is performed on said photo resist includes a terminal region of said gate line, a terminal region of said storage capacity line, and a terminal region of said data line, and a part of a contact hole for connecting said data line with said terminal region; and
removing a gate insulator film on a part of the contact hole for connecting the terminal region of said data line, said data line, and said terminal region by etching.

19. A method of manufacturing an active matrix substrate according to claim 11, wherein:
said method comprises the steps:
forming a ridge to prepare multi-domain of liquid crystal by inkjet method on said one of display electrodes.

20. A method of manufacturing an active matrix substrate according to claim 14, wherein:
a part or all of resist banks used in said inkjet method have light shielding property.

21. A method of manufacturing an active matrix substrate according to claim 20, wherein:
the resist bank used in said inkjet method is designed in laminated structure, and an insulator film is formed at least on a region where said channel is prepared.

22. A method of manufacturing an active matrix substrate according to claim 21, wherein:
said bank consists of a laminated layer of an insulating resist and a black color resist, the black color resist is on an upper layer, and exposure light quantity required for the insulating resist is higher than that of the black color resist.

23. A method of manufacturing an active matrix substrate according to claim 11, wherein:
a material different from the material of the active matrix substrate is used as the material of said counter substrate.

24. A method of manufacturing an active matrix substrate according to claim 17, wherein:
the resist bank prepared by said inkjet method fulfills a function of a mask for said etching and a function of a mask for fabricating a through-hole for forming said common electrode connection, and said method comprises the steps of:
performing aching after etching is carried out on said gate insulator film, and forming said the other of display electrodes when said data line terminal region is connected;
forming an interlayer insulator film on the uppermost surface of said active substrate, and forming a resist bank for half-tone exposure on said interlayer insulator film;
removing etching from the interlayer insulator film to cover said gate line and a terminal region of said data line by using said bank as a mask, and forming a through-hole to prepare said the other of display electrodes,
exposing said terminal region at the time of etching of said interlayer insulator film and forming said through-hole;
preparing an opening on the bank for forming the comb-like transparent conductive film by performing ashing on said bank resist; and
coating an ink containing a transparent conductive material on the opening of said bank, and a forming a contact between said the other of display electrodes and said the other of display electrodes connection.

25. A method of manufacturing an active matrix substrate according to claim 17, wherein:
the resist bank prepared by said inkjet method fulfills a function of a mask for said etching and a function of an etching mask for forming a through-hole for preparation of said the other of display electrodes connection, said method further comprises the steps of:
performing ashing after said gate insulator film is fabricated by etching, and forming said the other of display electrodes connection when connection is made with said terminal region of said data line;
forming an interlayer insulator film on the uppermost surface of said active substrate;
removing etching on said interlayer insulator film to cover said gate line, said storage capacity line, and said terminal region of said data line, and said the other of display electrodes connection by photolithographic process, and exposing the terminal region of said gate line and said data line, and said the other of display electrodes connection;
forming a transparent conductive film through vapor deposition of the transparent conductive material on said data line exposed and on the terminal region of said gate line, and on said the other of display electrodes connection; and
forming a comb-like electrode by using said resist mask.

26. A display device, having an active matrix substrate, said active matrix substrate comprises:
a gate line, a storage capacity line and a data line terminal formed on an insulator substrate;
a gate insulator film to cover said gate line and said storage capacity line;
a plurality of active layer islands formed in array arrangement on said gate insulator film and having an ohmic contact layer separated to a source electrode side and a drain electrode side via a gap to form a semiconductor layer and a channel on an upper layer of the semiconductor;
a source electrode connected to an ohmic contact layer on said source electrode side, and a data line connected to said source electrode; and
one of display electrodes formed by a drain electrode connected to ohmic contact layer on the drain electrode side and by a transparent conductive film continuously connected to the drain electrode, wherein:
said display device comprises:
a counter substrate with a color filter and the other of display electrodes on an insulator substrate different from said insulator substrate;
said active matrix substrate has said gate insulator film covered with said one of display electrodes in a region where said one of display electrodes is to be prepared;
said active matrix substrate has a resist bank to enclose the region where said one of display electrodes is to be prepared and said drain electrode, covering a counter gap of each of ohmic contact layers of said source electrode and said drain electrode, said source electrode and said data line, and also covering the data line of adjacent pixel;
a height from an upper surface of said insulator substrate of said transparent conductive film continuously connected to said one of display electrodes and said drain electrode is lower than a height from an upper surface of said insulator substrate of said resist bank;
an alignment layer is provided to cover each of said one of display electrodes of said active matrix substrate and said the other of display electrodes of said counter substrate; and
a liquid crystal is sealed in a gap where the active matrix substrate and each of alignment layers of said counter substrate are opposed to each other.

27. A display device, having an active matrix substrate, said active matrix substrate comprises:
a gate line, a storage capacity line and a data line terminal formed on an insulator substrate;
a gate insulator film to cover said gate line and said storage capacity line;
a plurality of active layer islands formed in array arrangement on said gate insulator film and having an ohmic contact layer separated to a source electrode side and a drain electrode side via a gap to form a semiconductor layer and a channel on an upper layer of the semiconductor;
a source electrode connected to an ohmic contact layer on said source electrode side, and a data line connected to said source electrode; and
one of display electrodes formed by a drain electrode connected to ohmic contact layer on the drain electrode side and by a transparent conductive film continuously connected to the drain electrode, wherein:
said display device comprises:
a counter substrate with the other of display electrodes on an insulator substrate different from said insulator substrate,
said active matrix substrate has a counter gap of each of ohmic contact layers of said source electrode and said drain electrode, and said source electrode and said data line, and has a resist bank to enclose a region where said one of display electrodes is to be prepared and said drain electrode, covering the data line of adjacent pixel;
a height from said insulator substrate of said transparent conductive film continuously connected to said one of display electrodes and said drain electrode provided on said color filter is lower than a height from said insulator substrate of said resist bank;
an alignment layer is provided to cover each of said one of display electrodes of said active matrix substrate and said the other of display electrodes of said counter substrate; and
a liquid crystal is sealed in a gap where the active matrix substrate and each of alignment layers of said counter substrate are opposed to each other.

28. A display device according to claim 26, wherein:
there is provided the other of display electrodes on said one of display electrodes via an interlayer insulator film.

29. A display device according to claim 27, wherein:
a material different from the material of the active matrix substrate is used as the material of said counter substrate.

30. A display device according to claim 27, wherein:
said bank is a laminated layer of an insulator film and a black color resist, and an insulating material is used at least to separate the channels from each other.
